(19) United States
(12) Patent Application Publication
(10) Pub. No.: US 2025/0385656 A1
(43) Pub. Date: Dec. 18, 2025

(54) THIN, FLEXIBLE ELECTRONIC DEVICES AND ASSOCIATED SYSTEMS AND METHODS

(71) Applicant: Massachusetts Institute of Technology, Cambridge, MA (US)

(72) Inventors: Jeehwan Kim, Cambridge, MA (US); Junmin Suh, Cambridge, MA (US); Yeongin Kim, Cincinnati, OH (US)

(73) Assignee: Massachusetts Institute of Technology, Cambridge, MA (US)

(21) Appl. No.: 18/877,675

(22) PCT Filed: Jun. 23, 2023
(86) PCT No.: PCT/US2023/026108

§ 371 Date: Dec. 20, 2024

Related U.S. Application Data
(60) Provisional application No. 63/355,531, filed on Jun. 24, 2022.

(51) Int. Cl. H03H 9/02; H03H 9/145; H03H 9/64

(52) U.S. Cl. CPC H03H 9/02574; H03H 9/02614; H03H 9/14541; H03H 9/642

(57) ABSTRACT

Devices (e.g., resonators) comprising a single-crystalline material, and related systems and methods, are generally described.

### RELATED APPLICATIONS

This application claims priority under 35 U.S.C. § 119(e) to U.S. Provisional Patent Application No. 63/355,531, filed Jun. 24, 2022, and entitled “Thin, Flexible Electronic Devices and Associated Systems and Methods,” which is incorporated herein by reference in its entirety for all purposes.

### TECHNICAL FIELD

Devices (e.g., resonators) comprising a single-crystalline material, and related systems and methods, are generally described.

### BACKGROUND

Conventional wireless electronic skin (e-skin)-based health monitoring systems rely on rigid circuit chips that consume significant power and compromise the overall flexibility of the device. Chip-less and wireless e-skin sensors based on inductor-capacitor (LC) resonators are limited to mechanical sensing with low sensitivities.

### SUMMARY

Devices (e.g., resonators) comprising a single-crystalline material, and related systems and methods, are generally described. The subject matter of the present invention involves, in some cases, interrelated products, alternative solutions to a particular problem, and/or a plurality of different uses of one or more systems and/or articles.

In certain embodiments, a surface acoustic wave resonator is described. In some embodiments, the surface acoustic wave resonator comprises a substrate; and a single crystalline piezoelectric material positioned at least partially over the substrate; wherein: the single-crystalline piezoelectric material has a thickness of less than or equal to 300 nm; and the resonator is configured such that the piezoelectric single-crystalline piezoelectric material resonates to generate a mechanical wave during operation of the resonator.

In some embodiments, the surface acoustic wave resonator comprises a substrate; and a single-crystalline piezoelectric material positioned at least partially over the substrate, wherein the resonator is configured such that the single-crystalline piezoelectric material resonates to generate a mechanical wave during operation of the resonator, and wherein the resonator has a minimum detectable strain less than or equal to 0.1% at an energy consumption less than or equal to 8×10⁻⁸ Joules per measurement.

Some aspects are related to devices. In some embodiments, the device comprises a substrate comprising a cavity; and a single-crystalline material positioned at least partially over the cavity of the substrate, wherein: the single-crystalline material is or is part of a freestanding layer; and the single-crystalline material has a thickness of less than or equal to 300 nm.

Certain aspects are related to methods of forming a device. In some embodiments, the method comprises transferring a single-crystalline material from a growth substrate to a receiving substrate such that at least a portion of the single-crystalline material is positioned over a cavity of the receiving substrate, wherein, after the transferring, the single-crystalline material is or is part of a freestanding layer, and the single-crystalline material has a thickness of less than or equal to 300 nm.

Certain aspects are related to methods of operating a surface acoustic wave resonator. In some embodiments, a method of operating a surface acoustic wave resonator comprising a single-crystalline piezoelectric material having a thickness of less than or equal to 300 nm comprises applying an electrical potential to the surface acoustic wave resonator such that the single-crystalline piezoelectric material resonates to generate a mechanical wave; and determining a change in a resonant frequency of the single-crystalline piezoelectric material in response to an environmental change.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIG. 1A shows, according to certain embodiments, a cross-sectional schematic diagram of a device;

FIG. 1B shows, according to certain embodiments, a cross-sectional schematic diagram of a device comprising an electrode array, an antenna, and an overlayer;

FIG. 2A shows, according to certain embodiments, a top-view schematic diagram of a substrate;

FIG. 2B shows, according to certain embodiments, a cross-sectional schematic diagram of a substrate;

FIG. 3 shows, according to certain embodiments, a top-view schematic diagram of a device;

FIG. 4 shows, according to certain embodiments, a top-view schematic diagram of a device positioned over a portion of skin of a user;

FIG. 5 shows, according to certain embodiments, a method of forming a device;

FIG. 6 shows, according to certain embodiments, a comparison between conventional wireless e-skin devices based on integrated circuit chips (left) and chip-less wireless e-skin devices based on source acoustic wave resonators comprising a single-crystalline material (right);

FIG. 7 shows, according to certain embodiments, an estimation of the minimum single-crystalline material thickness for conformal lamination on human skin;

FIG. 8 shows, according to certain embodiments, a high-resolution X-ray diffraction (HRXRD) phi scan of a 200 nm-thick remote epitaxial GaN film;

FIG. 9 shows, according to certain embodiments, a transmission electron microscopy (TEM) image and associated selective-area diffraction images of a freestanding 200 nm-thick GaN nanomembrane;

FIG. 10 shows, according to certain embodiments, scanning electron microscopy (SEM) images of GaN e-skin devices with 1800 nm-thick (left) and 200 nm-thick GaN (right) attached on skin replica samples;

FIG. 11 shows, according to certain embodiments, the responsivity of single-crystalline and polycrystalline GaN ultraviolet (UV) sensors;

FIG. 12 shows, according to certain embodiments, response/recovery speeds and selectivities of absorption of UV light over white light for single-crystalline (left) and polycrystalline GaN (right) UV sensors;

FIG. 13 shows, according to certain embodiments, the consistency of UV response of single-crystalline and polycrystalline GaN UV sensors;

FIG. 14 shows, according to certain embodiments, the calculated electromechanical coupling coefficient (k²) of GaN surface acoustic wave (SAW) devices by function of GaN thickness;

FIG. 15 shows, according to certain embodiments, the displacement of a GaN SAW;

FIG. 16 shows, according to certain embodiments, conductance and susceptance of a single-crystalline GaN SAW device used to extract experimental k²;

FIG. 17 shows, according to certain embodiments, a benchmark of extracted k² as a function of normalized thicknesses of GaN;

FIG. 18 shows, according to certain embodiments, a schematic illustration and optical images of a GaN SAW e-skin strain sensor;

FIG. 19 shows, according to certain embodiments, a resonant frequency shift as a function of strain for a GaN SAW e-skin strain sensor;

FIG. 20 shows, according to certain embodiments, a measurement of the minimum detectable strain of a GaN SAW e-skin strain sensor;

FIG. 21 shows, according to certain embodiments, a benchmark of minimum detectable strain and energy consumption for battery-less wireless e-skin strain sensors;

FIG. 22 shows, according to certain embodiments, wireless pulse measurements using a GaN SAW e-skin strain sensor;

FIG. 23 shows, according to certain embodiments, schematic illustrations and an optical microscope image of wireless ion sensors based on a GaN SAW device coated with an ion-selective membrane;

FIG. 24 shows, according to certain embodiments, a resonant frequency shift in the wireless signals obtained from a GaN SAW ion sensor in response to changes in ion concentration;

FIG. 25 shows, according to certain embodiments, continuous wireless recordings collected from an GaN SAW ion sensor;

FIG. 26 shows, according to certain embodiments, a calibration of the responsivity of a GaN SAW ion sensor to variation in ion concentration;

FIG. 27 shows, according to certain embodiments, photographs and microscopy images of an e-skin device attached on the back of a hand (top), in vivo recordings of the variation in ion concentration in sweat using a wireless GaN SAW-based e-skin device and a reference conductometer (middle), and an in vivo recording of the skin temperature obtained by thermometer (bottom);

FIG. 28 shows, according to certain embodiments, continuous wireless recordings collected by a GaN SAW UV sensor in response to exposures of UV light and white light;

FIG. 29 shows, according to certain embodiments, a calibration of the responsivity of a GaN SAW UV sensor to exposures of different UV light intensities;

FIG. 30 shows, according to certain embodiments, a schematic illustration for the production of a GaN nanomembrane via remote homoepitaxy;

FIGS. 31A-31D show, according to certain embodiments, a schematic illustration for the fabrication of a GaN e-skin device;

FIGS. 32A-32B show, according to certain embodiments, optical microscopy images from the fabrication process of a GaN e-skin device;

FIGS. 33A-33C show, according to certain embodiments, a schematic illustration for the fabrication of a GaN e-skin device;

FIG. 34 shows, according to certain embodiments, photographs a fabricated GaN e-skin device;

FIG. 35 shows, according to certain embodiments, chemical structures of epoxy adhesive precursors;

FIG. 36 shows, according to certain embodiments, schematic illustrations of a wireless e-skin device measurement system;

FIG. 37 shows, according to certain embodiments, a S₁₁ return loss of the wireless measurement system;

FIG. 38A shows, according to certain embodiments, a real-time output response of a GaN SAW e-skin strain sensor during compressive strain;

FIG. 38B shows, according to certain embodiments, a real-time output response of a GaN SAW e-skin strain sensor during tensile strain;

FIG. 39 shows, according to certain embodiments, an output response of a GaN SAW e-skin strain sensor depending on strain;

FIG. 40A shows, according to certain embodiments, continuous wireless recordings of the baseline noise in GaN SAW strain sensors placed off-skin;

FIG. 40B shows, according to certain embodiments, continuous wireless recordings of the baseline noise in GaN SAW strain sensors placed on-skin;

FIG. 41 shows, according to certain embodiments, the linearity of frequency shift as a function of bending strain;

FIG. 42 shows, according to certain embodiments, a schematic illustration of the total power consumption;

FIG. 43 shows, according to certain embodiments, an estimation of energy consumption per measurement for each component in FIG. 42 as functions of the distance between reader coil and SAW tag coil;

FIG. 44 shows, according to certain embodiments, photographs of an e-skin device attached on the neck area for pulse monitoring during daytime over a period of one week;

FIG. 45 shows, according to certain embodiments, wireless recordings of heart rate throughout the day over a period of one week;

FIG. 46 shows, according to certain embodiments, representative waveforms of the wirelessly recorded pulses in FIG. 45 for each day;

FIG. 47A shows, according to certain embodiments, wireless pulse measurement curves on day seven after rest;

FIG. 47B shows, according to certain embodiments, wireless pulse measurement curves on day seven after exercise;

FIG. 48A shows, according to certain embodiments, continuous wireless recordings from a GaN SAW-based strain sensor throughout 3000 bending cycles;

FIG. 48B shows, according to certain embodiments, magnified waveforms of the strain profile in FIG. 48A at different time points;

FIG. 49A shows, according to certain embodiments, a signal-to-noise ratio measured by a GaN SAW-based e-skin device when a coil antenna is displaced in the z-direction;

FIG. 49B shows, according to certain embodiments, a signal-to-noise ratio measured by a GaN SAW-based e-skin device when a coil antenna is displaced in the x-direction;

FIG. 49C shows, according to certain embodiments, a signal-to-noise ratio measured by a GaN SAW-based e-skin device when a coil antenna is displaced in the θ-direction;

FIG. 50A shows, according to certain embodiments, a resonant frequency shift when a coil antenna is displaced in the z-direction;

FIG. 50B shows, according to certain embodiments, a resonant frequency shift when a coil antenna is displaced in the x-direction;

FIG. 50C shows, according to certain embodiments, a resonant frequency shift when a coil antenna is displaced in the θ-direction;

FIG. 51 shows, according to certain embodiments, a heartbeat pulse frequency measurement under body motion;

FIG. 52 shows, according to certain embodiments, the components of an ion-selective membrane;

FIG. 53 shows, according to certain embodiments, a wirelessly recorded SAW ion sensor response towards exposures to aqueous solutions containing different ionic compositions of Na⁺, K⁺, and Ca²⁺ ions;

FIG. 54 shows, according to certain embodiments, a photograph of a wireless measurement system during in vivo sweat measurement;

FIG. 55 shows, according to certain embodiments, a schematic diagram of a GaN SAW UV sensor;

FIG. 56 shows, according to certain embodiments, an optical micrograph of a GaN SAW UV sensor;

FIG. 57 shows, according to certain embodiments, responsivities of wireless a GaN SAW UV sensor depending on wavelengths of input light;

FIG. 58 shows, according to certain embodiments, schematic illustrations of GaN SAW-based e-skin sensors for strain, UV light, and ion concentration;

FIG. 59 shows, according to certain embodiments, recorded responses of strain, UV, and ion sensors to variations in each type of input stimuli;

FIG. 60 shows, according to certain embodiments, a comparison between conventional chip-based wireless e-skin devices, soft material-based wireless e-skin devices, and a chip-less wireless e-skin device; and

FIGS. 61A-61B show, according to certain embodiments, compositions of ion-selective membranes.

### DETAILED DESCRIPTION

Devices (e.g., resonators) comprising a single-crystalline material, and related systems and methods, are generally described.

The inventors have recognized that there is an unmet need and opportunity for innovation in the field of resonators for use in wireless devices (e.g., e-skin-based health monitoring platforms). Conventional wireless e-skin-based health monitoring devices consist of rigid integrated circuit chips, such as near-field communication/radio frequency identification chips (NFC/RFID chips), microprocessors, or analog-to-digital converters (ADCs), that can compromise the overall flexibility of the device. Moreover, due to the power-constraint of the wireless e-skin systems, the high power consumption of these chips, which contain thousands of transistors, often leads to reduced sensitivity (due to the power-sensitivity tradeoff in analog-to-digital converters), significant heat generation, and reduced communication distance. LC resonator-based sensors have also been developed for chip-less and wireless e-skin devices, but the application of these sensors has been limited to strain and/or pressure detection with relatively low sensitivity due to the limitations of capacitive sensor designs.

Described herein is a device comprising a single-crystalline material that is or is part of a freestanding layer. The device may be, in some embodiments, a resonator, such as a surface acoustic wave resonator. The device is, in accordance with certain embodiments, configured such that the single-crystalline material serves as a piezoelectric resonator that generates a mechanical wave (e.g., a surface acoustic wave) during operation of the device. In some embodiments, the device may comprise a plurality of interdigitated electrodes in electrical communication with the single-crystalline material. The device may comprise an antenna in electrical communication with the plurality of interdigitated electrodes, in accordance with certain embodiments. The plurality of interdigitated electrodes is, in accordance with some embodiments, configured to deliver electrical energy from the antenna to the single-crystalline material, which converts the input electrical signal into a mechanical wave (e.g., a surface acoustic wave). The frequency of the mechanical wave may, in some embodiments, be sensitive to an environmental change resulting from one or more stimuli, such as mechanical strain, light exposure, and/or mass changes. In certain embodiments, the mechanical wave, after exposure to one or more environmental changes, is converted back into an electrical signal and retransmitted back through the antenna. In accordance with some embodiments, changes in the resonant frequency of the mechanical wave resulting from the one or more environmental changes yields information about the stimulus/stimuli (e.g., mechanical, optical, and/or biochemical stimuli). According to some embodiments, configuring the device in this way advantageously provides a multi-modality chip-less wireless sensor that is flexible and functions to detect one or more environmental changes (e.g., a mechanical strain, light, and/or chemical concentrations) with high sensitivity and without high-power consumption.

The single-crystalline material is grown (e.g., epitaxially grown), in certain embodiments, over a two-dimensional (2D) material positioned over a growth substrate that is lattice-matched with the single-crystalline material. In some such embodiments, a potential field from the growth substrate reaches beyond the 2D material such that the growth substrate seeds the growth of the single-crystalline film, even in cases where the 2D material is continuous. That is to say, the growth substrate can, in some embodiments, seed the growth of the single-crystalline material even when the 2D material is not patterned or otherwise arranged to have through thickness defects that allow for direct contact between the growth substrate and the single-crystalline film. In some embodiments, the potential field from the growth substrate penetrates through the 2D material to facilitate growth of the single-crystalline material with substantially no defects. In certain embodiments, the single-crystalline material may then be transferred from the growth substrate to a preconfigured receiving substrate, thereby bypassing the need to back-etch the receiving substrate to reach the single-crystalline material. According to certain embodiments, the epitaxial growth of the single-crystalline material advantageously yields a freestanding layer with an ultrathin thickness (e.g., less than or equal to 300 nm) that is stretchable and configured to conform to a portion of skin of a user for long-term wearability and biocompatibility.

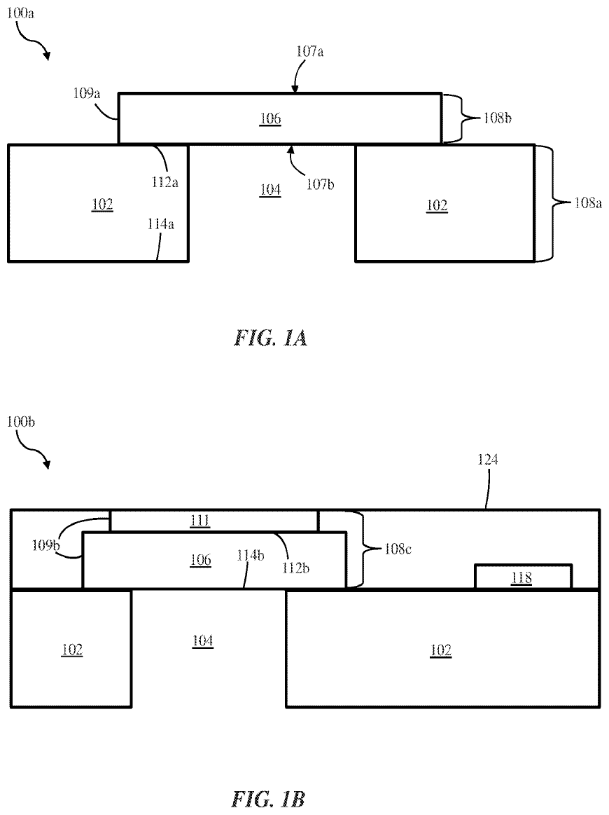

In some embodiments, the device comprises a substrate. The substrate may, in certain embodiments, comprise a cavity. FIG. 1A shows, according to certain embodiments, a cross-sectional schematic diagram of a device. As shown in FIG. 1A, device 100a comprises substrate 102 comprising cavity 104. In certain embodiments, the cavity may advantageously allow the single-crystalline material to resonate, as explained in further detail herein.

In certain embodiments, cavity 104 may extend through the bulk of substrate 102, for example, from first surface 112a of substrate 102 to second surface 114a of substrate 102 that is opposite first surface 112a. In other embodiments, although not shown in the figures, the cavity may extend only partially through the bulk of the substrate.

The cavity may be any of a variety of suitable shapes and/or sizes. According to certain embodiments, for example, the cavity may be square shaped, circular shaped, and/or dumbbell shaped. Other shapes are also possible.

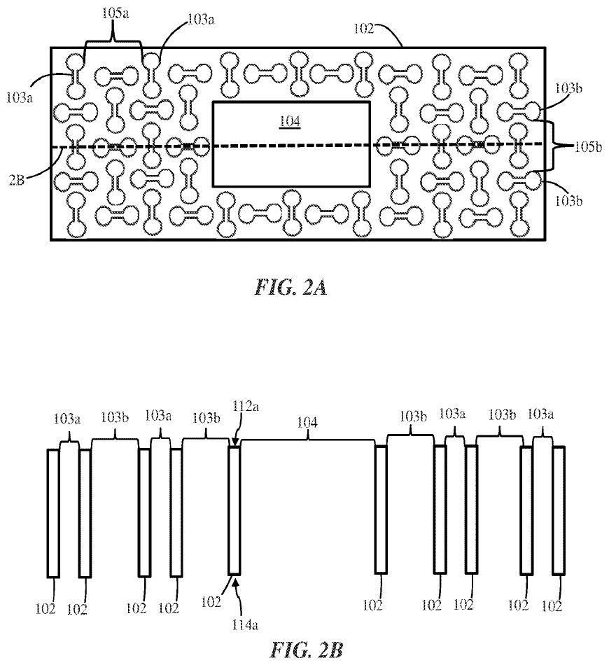

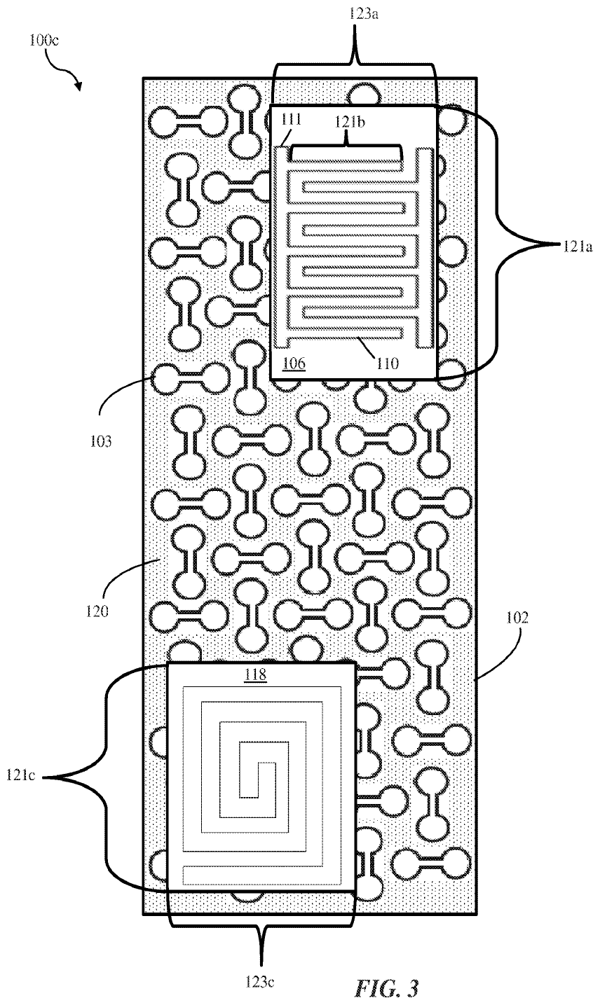

According to certain embodiments, the substrate may comprise one or more auxetic holes (e.g., a plurality of auxetic holes). FIG. 2A shows, according to certain embodiments, a top-view schematic diagram of a substrate, and FIG. 2B shows, according to certain embodiments, a cross-sectional schematic diagram of the substrate taken along line 2B in FIG. 2A. As shown in FIGS. 2A and 2B, substrate 102 comprises a plurality of auxetic holes 103 (e.g., auxetic holes 103a and 103b). Advantageously, the one or more auxetic holes may facilitate the stretchability, conformability, and breathability of the device, according to some embodiments. In certain embodiments, the one or more auxetic holes may advantageously facilitate the exposure of the single-crystalline material to one or more stimuli (e.g., UV light, ions).

In some embodiments, and as shown in FIG. 2B, one or more auxetic holes 103 may extend through the bulk of substrate 102, for example, from first surface 112a of substrate 102 to second surface 114a of substrate 102 that is opposite first surface 112a. In other embodiments, although not shown in the figures, the one or more auxetic holes may extend only partially through the bulk of the substrate.

According to certain embodiments, and as shown in FIG. 2A, one or more auxetic holes 103 may be dumbbell holes. Auxetic holes with other shapes are also possible (e.g., square shaped auxetic holes, circular shaped auxetic holes, etc.), as the disclosure is not meant to be limiting in this regard.

The plurality of auxetic holes may be patterned, according to certain embodiments. In some embodiments, for example, a first portion of the plurality of auxetic holes may be substantially aligned in a first orientation, and a second portion of the plurality of auxetic holes may be substantially aligned in a second orientation. Referring to FIG. 2A, for example, auxetic holes 103a are substantially aligned in a first orientation and auxetic holes 103b are substantially aligned in a second orientation.

According to certain embodiments, the first portion of the plurality of auxetic holes substantially aligned in the first orientation may be substantially evenly spaced. Referring to FIG. 2A, for example, distance 105a between adjacent auxetic holes 103a substantially aligned in the first orientation may be substantially equal, according to certain embodiments. In some embodiments, the second portion of the plurality of auxetic holes substantially aligned in the second orientation may be substantially evenly spaced. Referring, for example, to FIG. 2A, distance 105b between adjacent auxetic holes substantially aligned in the second orientation may be substantially equal, according to some embodiments. In other embodiments, at least a portion of the plurality of auxetic holes (e.g., the first portion of the plurality of auxetic holes aligned in the first orientation and/or the second portion of the plurality of auxetic holes aligned in the second orientation) may be randomly dispersed, as the disclosure is not meant to be limiting in this regard.

The substrate may comprise any of a variety of suitable materials. In some embodiments, for example, the substrate comprises a polyimide and/or polydimethylsiloxane (PDMS). Other materials are also possible. The substrate cavity and/or the one or more auxetic holes may be occupied by any of a variety of suitable non-solid materials (e.g., one or more gases, one or more liquids), in accordance with certain embodiments.

The substrate may have any of a variety of suitable thicknesses. Referring to FIG. 1A, for example, substrate 102 has thickness 108a, in accordance with certain embodiments. In some embodiments, the substrate has a thickness of less than or equal to 5 centimeters, less than or equal to 1 centimeter, less than or equal to 5 millimeters, less than or equal to 1 millimeter, less than or equal to 500 micrometers, less than or equal to 200 micrometers, less than or equal to 100 micrometers, less than or equal to 50 micrometers, less than or equal to 30 micrometers, less than or equal to 25 micrometers, less than or equal to 20 micrometers, less than or equal to 15 micrometers, less than or equal to 10 micrometers, less than or equal to 5 micrometers, or less. In certain embodiments, the substrate has a thickness of greater than or equal to 1 micrometer, greater than or equal to 5 micrometers, greater than or equal to 10 micrometers, greater than or equal to 15 micrometers, greater than or equal to 20 micrometers, greater than or equal to 25 micrometers, greater than or equal to 50 micrometers, greater than or equal to 100 micrometers, greater than or equal to 200 micrometers, greater than or equal to 500 micrometers, or more. Combinations of the above recited ranges are possible (e.g., the substrate has a thickness of greater than or equal to 1 micrometer and less than or equal to 1 centimeter, greater than or equal to 1 micrometer and less than or equal to 1 millimeter, or greater than or equal to 10 micrometers and less than or equal to 20 micrometers). Other ranges are also possible.

According to certain embodiments, the device comprises a single-crystalline material. Referring, for example, to FIG. 1A, device 100a comprises single-crystalline material 106, in accordance with certain embodiments. In some embodiments, single-crystalline material 106 may be positioned at least partially over cavity 104 of substrate 106. FIG. 3 shows, according to certain embodiments, a top-view schematic diagram of a device. Referring to FIG. 3, single-crystalline material 106 may be positioned at least partially over one or more auxetic holes 103 of substrate 106, in accordance with certain embodiments. Advantageously, configuring the device in this way (e.g., positioned at least partially over the cavity of the substrate, positioned at least partially over one or more auxetic holes of the substrate) acoustically isolates the single-crystalline material and allows the single-crystalline material to resonate, in accordance with some embodiments.

In some embodiments, the single-crystalline material is or is part of a freestanding layer. Referring to FIG. 1A, for example, single-crystalline material 106 is freestanding layer 109a, in accordance with certain embodiments. FIG. 1B shows, according to certain embodiments, a cross-sectional schematic diagram of a device comprising an electrode array, an antenna, and an overlayer. Referring to FIG. 1B, single-crystalline material 106 is part of freestanding layer 109b.

A “layer” is a form factor having a thickness dimension and two lateral dimensions, with each lateral dimension perpendicular to the thickness and to the other lateral dimension, and in which each lateral dimension has a length that is at least three (3) times the thickness dimension. A layer also has two “major surfaces,” which are surfaces that are defined by the two lateral dimensions. In FIG. 1A, for example, layer of single-crystalline material 106 has major surface 107a and major surface 107b. In certain embodiments, the layer or a portion thereof (e.g., the freestanding layer or the freestanding portion of the freestanding layer, the layer of the single-crystalline material or the freestanding portion of the single-crystalline material, or any other layer or layer portion described herein) is arranged such that the length of each lateral dimension is at least 5 times, at least 10 times, at least 1,000 times, at least 100,000 times, or at least 1,000,000 times the thickness.

As used herein, a layer is said to be “freestanding” if, for at least a portion of the layer (referred to as the “freestanding portion” of the freestanding layer), the major surfaces of the layer are not in contact with another solid material. The freestanding layer will generally be bound, in accordance with certain embodiments, along some or all of its edges to a solid substrate, with the freestanding portion of the layer being free of contact on both sides with solid material. According to certain embodiments, the single-crystalline material that is or is part of the freestanding layer may be configured such that the single-crystalline material is positioned and/or aligned over the cavity of the substrate (and, in some embodiments, portioned and/or aligned over one or more auxetic holes of the substrate). Configuring the device in this way advantageously allows the single-crystalline material to resonate (e.g., through the cavity of the substrate and/or the one or more auxetic holes of the substrate).

As explained in further detail below, the freestanding layer may comprise, in addition to the single-crystalline material, a plurality of interdigitated electrodes (e.g., over the single-crystalline material) and/or an overlayer (e.g., a protective material, a stimuli detecting material), in accordance with certain embodiments.

In some embodiments, the single-crystalline material is a piezoelectric material (e.g., a single-crystalline piezoelectric material). As used herein, the term “piezoelectric material” is given its ordinary meaning in the art and generally refers to a material that has the ability to generate electrical charge from applied mechanical stress. In some embodiments, the piezoelectric material comprises a semiconductor material. In certain embodiments, the piezoelectric material comprises an insulator material.

According to some embodiments, the single-crystalline material comprises a semiconductor material (e.g., a single-crystalline semiconductor material).

In certain embodiments, the single-crystalline material comprises a III-nitride material. The term “III-nitride material” is used herein to refer to any Group III element-nitride compound. Non-limiting examples of III-nitride materials include gallium nitride (GaN), boron nitride (BN), aluminum nitride (AlN), indium nitride (InN), and thallium nitride (TlN), as well as any alloys including Group III elements and Group V elements (e.g., AlₓGa₍₁₋ₓ₎N, AlₓIn_{y}Ga_{(1-x-y)}N, InₓGa₍₁₋ₓ₎N, AlₓIn₍₁₋ₓ₎N, GaAsₐP_{b}N_{(1-a-b)}, AlₓIn_{y}Ga_{(1-x-y)}AsₐP_{b}N_{(1-a-b)}, and the like). III-nitride materials may be doped n-type or p-type, or may be intrinsic.

The phrase “gallium nitride material” refers to gallium nitride (GaN) and any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphoride nitride (GaAsₐP_{b}N_{(1-a-b)}), aluminum indium gallium arsenide phosphoride nitride (AlₓIn_{y}Ga_{(1-x-y)}AsₐP_{b}N_{(1-a-b)}), and the like. In certain embodiments, the gallium nitride material comprises GaN.

The phrase “aluminum nitride material” refers to aluminum nitride (AlN) and any of its alloys, such as aluminum gallium nitride (AlₓGa₍₁₋ₓ₎N), aluminum indium nitride (AlₓIn₍₁₋ₓ₎N), aluminum indium gallium nitride (AlₓIn_{y}Ga_{(1-x-y)}N), aluminum indium gallium arsenide phosphoride nitride (AlₓIn_{y}Ga_{(1-x-y)}AsₐP_{b}N_{(1-a-b)}), and the like. In certain embodiments, the aluminum nitride material comprises AlN.

According to certain embodiments, the single-crystalline material comprises a III-phosphide material. The term “III-phosphide material” is used herein to refer to any Group III element-phosphide compound. Non-limiting examples of III-phosphide materials include gallium phosphide (GaP), boron phosphide (BP), aluminum phosphide (AlP), indium phosphide (InP), and thallium phosphide (TlP), as well as any alloys including Group III elements and Group V elements (e.g., AlₓGa₍₁₋ₓ₎P, AlₓIn_{y}Ga_{(1-x-y)}P, InₓGa₍₁₋ₓ₎P, AlₓIn₍₁₋ₓ₎P, GaAsₐP_{b}N_{(1-a-b)}, AlₓIn_{y}Ga_{(1-x-y)}AsₐP_{b}N_{(1-a-b)}, and the like). III-phosphide materials may be doped n-type or p-type, or may be intrinsic.

In some embodiments, the single-crystalline material comprises a III-arsenide material. The term “III-arsenide material” is used herein to refer to any Group III element-arsenide compound. Non-limiting examples of III-arsenide materials include gallium arsenide (GaAs), boron arsenide (BAs), aluminum arsenide (AlAs), indium arsenide (InAs), and thallium arsenide (TlAs), as well as any alloys including Group III elements and Group V elements (e.g., AlₓGa₍₁₋ₓ₎As, AlₓIn_{y}Ga_{(1-x-y)}As, InₓGa₍₁₋ₓ₎As, AlₓIn₍₁₋ₓ₎P, GaAsₐAs_{b}N_{(1-a-b)}, AlₓIn_{y}Ga_{(1-x-y)}AsₐP_{b}N_{(1-a-b)}, and the like). III-arsenide materials may be doped n-type or p-type, or may be intrinsic.

In certain embodiments, the single-crystalline material comprises an oxide. Non-limiting examples of oxides include barium titanate (BaTiO₃ or BTO), barium strontium titanate (BaₓSr₁₋ₓTiO₃ or BST), strontium titanate (SrTiO₃ or STO), strontium ruthenium oxide (SrRuO₃ or SRO), lanthanum aluminate (LaAlO₃ or LAO), lead magnesium niobate-lead titanate (Pb(Mg_{1/3}Nb_{2/3})O₃—PbTiO₃ or PMN-PT), yttrium iron garnet (Y₃Fe₅O₁₂ or YIG), lithium niobate (LiNbO₃), lithium titanate (Li₂TiO₃), zinc oxide (ZnO), and the like.

The single-crystalline material may have any of a variety of suitable thicknesses. Referring to FIG. 1A, for example, single-crystalline material 106 has thickness 108b, in accordance with some embodiments. In certain embodiments, the single-crystalline material has a thickness of less than or equal to 300 nm, less than or equal to 250 nm, less than or equal to 200 nm, less than or equal to 150 nm, less than or equal to 100 nm, less than or equal to 50 nm, or less. In some embodiments, the single-crystalline material has a thickness of greater than or equal to 10 nm, greater than or equal to 50 nm, greater than or equal to 100 nm, greater than or equal to 150 nm, greater than or equal to 200 nm, or greater than or equal to 250 nm. Combinations of the above recited ranges are possible (e.g., the single-crystalline material has a thickness of greater than or equal to 10 nm and less than or equal to 300 nm, or greater than or equal to 100 nm and less than or equal to 200 nm). Other ranges are also possible.

The freestanding layer may have any of a variety of suitable thicknesses. Referring to FIGS. 1A and 1B, for example, freestanding layer 109a has thickness 108b, and freestanding layer 109b has thickness 108c, respectively, in accordance with some embodiments. In certain embodiments, the freestanding layer has a thickness of less than or equal to 100 μm, less than or equal to 10 μm, less than or equal to 1 μm, less than or equal to 500 nm, less than or equal to 300 nm, less than or equal to 100 nm, or less. In some embodiments, the freestanding layer has a thickness of greater than or equal to 10 nm, greater than or equal to 100 nm, greater than or equal to 300 nm, greater than or equal to 500 nm, greater than or equal to 1 μm, greater than or equal to 10 μm, or greater. Combinations of the above recited ranges are possible (e.g., the freestanding layer has a thickness of greater than or equal to 10 nm and less than or equal to 100 μm, or greater than or equal to 200 nm and less than or equal to 500 nm). Other ranges are also possible.

The single-crystalline material may have any of a variety of suitable lengths and/or widths. Referring to FIG. 3, single-crystalline material 106 has length 121a and width 123a, in accordance with some embodiments. In some embodiments, the single-crystalline material has a length and/or width of greater than or equal to 1 μm, greater than or equal to 10 μm, greater than or equal to 100 μm, greater than or equal to 300 μm, greater than or equal to 500 μm, greater than or equal to 1 mm, greater than or equal to 10 mm, or greater. In certain embodiments, the single-crystalline material has a length and/or width of less than or equal to 100 mm, less than or equal to 10 mm, less than or equal to 1 mm, less than or equal to 500 μm, less than or equal to 300 μm, less than or equal to 100 μm, less than or equal to 10 μm, or less. Combinations of the above recited ranges are possible (e.g., the single-crystalline material has a length and/or width of greater than or equal to 1 μm and less than or equal to 100 mm, or greater than or equal to 300 μm and less than or equal to 1 mm). Other ranges are also possible. In certain embodiments, the freestanding portion of the single-crystalline material (when it is freestanding) has a length and/or width of greater than or equal to 1 μm, greater than or equal to 10 μm, greater than or equal to 100 μm, greater than or equal to 300 μm, greater than or equal to 500 μm, greater than or equal to 1 mm, greater than or equal to 10 mm, or greater. In certain embodiments, the freestanding portion of the single-crystalline material (when it is freestanding) has a length and/or width of less than or equal to 100 mm, less than or equal to 10 mm, less than or equal to 1 mm, less than or equal to 500 μm, less than or equal to 300 μm, less than or equal to 100 μm, less than or equal to 10 μm, or less. Combinations of the above recited ranges are possible (e.g., the freestanding portion of the single-crystalline material has a length and/or width of greater than or equal to 1 μm and less than or equal to 100 mm, or greater than or equal to 300 μm and less than or equal to 1 mm). Other ranges are also possible.

The freestanding layer may have any of a variety of suitable lengths and/or widths. In some embodiments, the freestanding layer has a length and/or width of greater than or equal to 1 μm, greater than or equal to 10 μm, greater than or equal to 100 μm, greater than or equal to 300 μm, greater than or equal to 500 μm, greater than or equal to 1 mm, greater than or equal to 10 mm, or greater. In certain embodiments, the freestanding layer has a length and/or width of less than or equal to 100 mm, less than or equal to 10 mm, less than or equal to 1 mm, less than or equal to 500 μm, less than or equal to 300 μm, less than or equal to 100 μm, less than or equal to 10 μm, or less. Combinations of the above recited ranges are possible (e.g., the freestanding layer has a length and/or width of greater than or equal to 1 μm and less than or equal to 100 mm, or greater than or equal to 300 μm and less than or equal to 1 mm). Other ranges are also possible. In certain embodiments, the freestanding portion of the freestanding layer has a length and/or width of greater than or equal to 1 μm, greater than or equal to 10 μm, greater than or equal to 100 μm, greater than or equal to 300 μm, greater than or equal to 500 μm, greater than or equal to 1 mm, greater than or equal to 10 mm, or greater. In certain embodiments, the freestanding portion of the freestanding layer has a length and/or width of less than or equal to 100 mm, less than or equal to 10 mm, less than or equal to 1 mm, less than or equal to 500 μm, less than or equal to 300 μm, less than or equal to 100 μm, less than or equal to 10 μm, or less. Combinations of the above recited ranges are possible (e.g., the freestanding portion of the freestanding layer has a length and/or width of greater than or equal to 1 μm and less than or equal to 100 mm, or greater than or equal to 300 μm and less than or equal to 1 mm). Other ranges are also possible.

The single-crystalline material may have any of a variety of suitable facial surface areas. The term “facial surface area” is used to describe the surface area of a major surface of the layer (which, generally, is the same for each major surface of the layer). In some embodiments, the single-crystalline material has a major surface having a facial surface area of greater than or equal to 1 μm², greater than or equal to 10 μm², greater than or equal to 100 μm², greater than or equal to 1 mm², greater than or equal to 10 mm², greater than or equal to 100 mm², greater than or equal to 1,000 mm², or greater. In certain embodiments, the single-crystalline material has a major surface having a facial surface area of less than or equal to 10,000 mm², less than or equal to 1,000 mm², less than or equal to 100 mm², less than or equal to 10 mm², less than or equal to 1 mm², less than or equal to 100 μm², less than or equal to 10 μm², or less. Combinations of the above recited ranges are possible (e.g., the single-crystalline material has a major surface having a facial surface area of greater than or equal to 1 μm² and less than or equal to 10,000 mm², or greater than or equal to 1 mm² and less than or equal to 10 mm²). Other ranges are also possible. In some embodiments, the freestanding portion of the single-crystalline material (when it is freestanding) has a major surface having a facial surface area of greater than or equal to 1 μm², greater than or equal to 10 μm², greater than or equal to 100 μm², greater than or equal to 1 mm², greater than or equal to 10 mm², greater than or equal to 100 mm², greater than or equal to 1,000 mm², or greater. In certain embodiments, the freestanding portion of the single-crystalline material (when it is freestanding) has a major surface having a facial surface area of less than or equal to 10,000 mm², less than or equal to 1,000 mm², less than or equal to 100 mm², less than or equal to 10 mm², less than or equal to 1 mm², less than or equal to 100 μm², less than or equal to 10 μm², or less. Combinations of the above recited ranges are possible (e.g., the freestanding portion of the single-crystalline material has a major surface having a facial surface area of greater than or equal to 1 μm² and less than or equal to 10,000 mm², or greater than or equal to 1 mm² and less than or equal to 10 mm²). Other ranges are also possible.

The freestanding layer may have any of a variety of suitable facial surface areas. In some embodiments, the freestanding layer has a major surface having a facial surface area of greater than or equal to 1 μm², greater than or equal to 10 μm², greater than or equal to 100 μm², greater than or equal to 1 mm², greater than or equal to 10 mm², greater than or equal to 100 mm², greater than or equal to 1,000 mm², or greater. In certain embodiments, the freestanding layer has a major surface having a facial surface area of less than or equal to 10,000 mm², less than or equal to 1,000 mm², less than or equal to 100 mm², less than or equal to 10 mm², less than or equal to 1 mm², less than or equal to 100 μm², less than or equal to 10 μm², or less. Combinations of the above recited ranges are possible (e.g., the freestanding layer has a major surface having a facial surface area of greater than or equal to 1 μm² and less than or equal to 10,000 mm², or greater than or equal to 1 mm² and less than or equal to 10 mm²). Other ranges are also possible. In some embodiments, the freestanding portion of the freestanding layer has a major surface having a facial surface area of greater than or equal to 1 μm², greater than or equal to 10 μm², greater than or equal to 100 μm², greater than or equal to 1 mm², greater than or equal to 10 mm², greater than or equal to 100 mm², greater than or equal to 1,000 mm², or greater. In certain embodiments, the freestanding portion of the freestanding layer has a major surface having a facial surface area of less than or equal to 10,000 mm², less than or equal to 1,000 mm², less than or equal to 100 mm², less than or equal to 10 mm², less than or equal to 1 mm², less than or equal to 100 μm², less than or equal to 10 μm², or less. Combinations of the above recited ranges are possible (e.g., the freestanding portion of the freestanding layer has a major surface having a facial surface area greater than or equal to 1 μm² and less than or equal to 10,000 mm², or greater than or equal to 1 mm² and less than or equal to 10 mm²). Other ranges are also possible.

The single-crystalline material may have any of a variety of suitable electromechanical coupling coefficients (k²). In some embodiments, for example, the single-crystalline material has a k² of greater than or equal to 0.001%, greater than or equal to 0.01%, greater than or equal to 0.1%, greater than or equal to 1%, greater than or equal to 10%, greater than or equal to 20%, greater than or equal to 40%, greater than or equal to 60%, or greater than or equal to 80%. In certain embodiments, the single-crystalline material has a k² of less than or equal to 100%, less than or equal to 80%, less than or equal to 60%, less than or equal to 40%, less than or equal to 20%, less than or equal to 10%, less than or equal to 1%, less than or equal to 0.1%, or less than or equal to 0.01%. Combinations of the above recited ranges are possible (e.g., the single-crystalline material has a k² of greater than or equal to 0.001% and less than or equal to 100%, or greater than or equal to 1% and less than or equal to 10%). Other ranges are also possible.

According to certain embodiments, the value of k² is determined by measuring the reflection coefficient (S₁₁) of the interdigitated transducer, from which the conductance, G=Re(Y), and the susceptance, B=Im(Y), at a resonant peak are calculated, followed by calculating the electromechanical coupling coefficient (k²) using the equation, k²=π/4N (G/B)_{when f=f}_{ᵣ}, where N, f, and fᵣ are the number of interdigitated electrodes, frequency, and resonant frequency, respectively.

The single-crystalline material may have any of a variety of suitable resonant frequencies. In some embodiments, for example, the single-crystalline material has a resonant frequency greater than or equal to 1 kHz, greater than or equal to 10 kHz, greater than or equal to 100 kHz, greater than or equal to 1 MHz, greater than or equal to 10 MHz, greater than or equal to 100 MHz, greater than or equal to 1 GHz, or greater than or equal to 10 GHz. In certain embodiments, the single-crystalline material has a resonant frequency less than or equal to 100 GHz, less than or equal to 10 GHz, less than or equal to 1 GHz, less than or equal to 100 MHz, less than or equal to 10 MHz, less than or equal to 1 MHz, less than or equal to 100 kHz, or less than or equal to 10 kHz. Combinations of the above recited ranges are also possible (e.g., the single-crystalline material has a resonant frequency greater than or equal to 1 kHz and less than or equal to 100 GHz, or greater than or equal to 10 MHz and less than or equal to 100 MHz). Other ranges are also possible.

In certain embodiments, the resonant frequency of the single-crystalline material is measured by exposing the device to electromagnetic (EM) waves (e.g., initiated by an external source, such as a wireless reader) and scanning the return loss reflection coefficient (S₁₁) over a range of frequencies using the external source.

According to certain embodiments, although not shown in the figures, one or more intermediate layers may be positioned between the substrate and the single-crystalline material. In some such embodiments, the one or more intermediate layers may be configured as described above with respect to the substrate.

According to certain embodiments, the device comprises a plurality of interdigitated electrodes. Referring to FIG. 3, for example, device 100c may comprise a plurality of interdigitated electrodes 110, in accordance with certain embodiments. In some embodiments, the plurality of interdigitated electrodes 110 may be connected to electrode array 111. In some embodiments, the plurality of interdigitated electrodes connected to the electrode array may be an interdigitated transducer (IDT).

The plurality of interdigitated electrodes 110 and electrode array 111 may, in some embodiments, be in electrical communication with single-crystalline material 106. Referring, for example, to FIG. 1B, electrode array 111, and a plurality of interdigitated electrodes connected thereto, may, in some embodiments, be over first surface 112b of single-crystalline material 106. In certain embodiments, first surface 112b of single-crystalline material 106 is opposite second surface 114b of single-crystalline material that is positioned at least partially over cavity 104 of substrate 102. In some embodiments, each interdigitated electrode of the plurality of interdigitated electrodes may form a Schottky contact with the single-crystalline material.

In certain embodiments, the plurality of interdigitated electrodes are patterned. In some embodiments, for example, the distance between adjacent interdigitated electrodes may be substantially equal, according to certain embodiments. In some embodiments, the distance between adjacent interdigitated electrodes may be any of a variety of suitable distances (e.g., at least 1 nm, at least 10 nm, at least 50 nm, at least 100 nm, at least 200 nm, at least 300 nm, at least 400 nm, at least 500 nm, at least 1 μm, at least 2 μm, at least 5 μm, at least 10 μm, at least 20 μm, etc.). In other embodiments, at least a portion of the plurality interdigitated electrodes may be randomly dispersed, as the disclosure is not meant to be limiting in this regard.

The plurality of interdigitated electrodes may comprise any of a variety of suitable materials. In some embodiments, for example, the plurality of interdigitated electrodes comprise an electrically conductive material, such as one or more metals, one or more conductive ceramics, and/or one or more conductive polymers. In certain embodiments, the plurality of interdigitated electrodes comprise nickel nitride (NiNₓ), gold (Au), platinum (Pt), palladium (Pd), gold (Au), nickel (Ni), titanium (Ti), titanium nitride (TiN), chromium (Cr), aluminum (Al), silver (Ag), copper (Cu), molybdenum (Mo), iron (Fe), magnesium (Mg), zinc (Zn), and/or tungsten (W). Other materials are also possible.

The device may comprise any of a variety of suitable numbers of interdigitated electrodes. In some embodiments, for example, the device comprises at least 1, at least 10, at least 100, at least 1,000, at least 10,000, or at least 100,000 interdigitated electrodes. In certain embodiments, the device comprises less than or equal to 1,000,000, less than or equal to 100,000, less than or equal to 10,000, less than or equal to 1,000, less than or equal to 100, or less than or equal to 10 interdigitated electrodes. Combinations of the above recited ranges are possible (e.g., the device comprises at least 1 and less than or equal to 1,000,000 interdigitated electrodes, the device comprises at least 100 and less than or equal to 10,000 interdigitated electrodes). Other combinations are also possible.

Each interdigitated electrode of the plurality of interdigitated electrodes may have any of a variety of suitable lengths. Referring, for example, to FIG. 3, each interdigitated electrode 110 has length 121b, according to certain embodiments. In some embodiments, each interdigitated electrode has a length of less than or equal to 100 mm, less than or equal to 50 mm, less than or equal to 10 mm, less than or equal to 1 mm, less than or equal to 100 μm, less than or equal to 10 μm, less than or equal to 1 μm, less than or equal to 100 nm, less than or equal to 10 nm, or less. In certain embodiments, each interdigitated electrode has a length of greater than or equal to 1 nm, greater than or equal to 10 nm, greater than or equal to 100 nm, greater than or equal to 1 μm, greater than or equal to 10 μm, greater than or equal to 100 μm, greater than or equal to 1 mm, greater than or equal to 10 mm, greater than or equal to 50 mm, or greater. Combinations of the above recited ranges are possible (e.g., each interdigitated electrode has a length of greater than or equal to 1 nm and less than or equal to 100 mm, or greater than or equal to 1 μm and less than or equal to 100 μm). Other ranges are also possible.

Each interdigitated electrode of the plurality of interdigitated electrodes may have any of a variety of suitable facial surface areas. In some embodiments, each interdigitated electrode has major surface having a facial surface area of greater than or equal to 1 nm², greater than or equal to 10 nm², greater than or equal to 100 nm², greater than or equal to 1 μm², greater than or equal to 10 μm², greater than or equal to 100 μm², greater than or equal to 1 mm², greater than or equal to 10 mm², greater than or equal to 100 mm², or greater. In certain embodiments, each interdigitated electrode has a major surface having a facial surface area of less than or equal to 500 mm², less than or equal to 100 mm², less than or equal to 10 mm², less than or equal to 1 mm², less than or equal to 100 μm², less than or equal to 10 μm², less than or equal to 1 μm², less than or equal to 100 nm², less than or equal to 10 nm², or less. Combinations of the above recited ranges are possible (e.g., each interdigitated electrode has a major surface having a facial surface area of greater than or equal to 1 nm² and less than or equal to 500 mm², or greater than or equal to 10 m² and less than or equal to 100 m²). Other ranges are also possible.

According to some embodiments, the device comprises an antenna. Referring to FIGS. 1B and 3, for example, device 100 (e.g., device 100b in FIG. 1B and device 100c in FIG. 3) may comprise antenna 118, in accordance with some embodiments. In certain embodiments, the antenna may be a near-field antenna (e.g., a near-field electrically-small antenna) or a far-field antenna (e.g., a far-field loop antenna). Other antennas are also possible as the disclosure is not meant to be limiting in this regard.

The antenna may comprise any of a variety of suitable materials. In some embodiments, for example, the antenna comprises an electrically conductive material, such as one or more metals, one or more conductive ceramics, and/or one or more conductive polymers. In certain embodiments, the antenna comprises Ti, TiN, Au, Pt, Pd, Ni, NiNₓ, Cr, Al, Ag, Cu, Mo, Fe, Mg, Zn, and/or W. Other materials are also possible.

The antenna may have any of a variety of suitable shapes. In certain embodiments, for example, the antenna may be a square or rectangular patch antenna. In other embodiments, the antenna may be a circular loop antenna. Other shapes are also possible.

The antenna may have any of a variety of suitable lengths and/or widths. Referring, for example, to FIG. 3, antenna 118 has length 121c and width 123c, according to certain embodiments. In some embodiments, the antenna has a length and/or width of less than or equal to 50 mm, less than or equal to 10 mm, less than or equal to 1 mm, less than or equal to 100 μm, less than or equal to 10 μm, less than or equal to 1 μm, less than or equal to 500 nm, less than or equal to 100 nm, less than or equal to 10 nm, or less. In certain embodiments, the antenna has a length and/or width of greater than or equal to 1 nm, greater than or equal to 10 nm, greater than or equal to 100 nm, greater than or equal to 500 nm, greater than or equal to 1 μm, greater than or equal to 10 μm, greater than or equal to 100 μm, greater than or equal to 1 mm, greater than or equal to 10 mm, or greater. Combinations of the above recited ranges are possible (e.g., the antenna has a length and/or width of greater than or equal to 1 nm and less than or equal to 50 mm, or greater than or equal to 1 μm and less than or equal to 10 μm). Other ranges are also possible.

The antenna may have any of a variety of suitable facial surface areas. In some embodiments, the antenna has major surface having a facial surface area of greater than or equal to 1 nm², greater than or equal to 10 nm², greater than or equal to 100 nm², greater than or equal to 1 μm², greater than or equal to 10 μm², greater than or equal to 100 μm², greater than or equal to 1 mm², greater than or equal to 10 mm², greater than or equal to 100 mm², greater than or equal to 1,000 mm², or greater. In certain embodiments, the antenna has a major surface having a facial surface area of less than or equal to 5,000 mm², less than or equal to 1,000 mm², less than or equal to 100 mm², less than or equal to 10 mm², less than or equal to 1 mm², less than or equal to 100 μm², less than or equal to 10 μm², less than or equal to 1 μm², less than or equal to 100 nm², less than or equal to 10 nm², or less. Combinations of the above recited ranges are possible (e.g., the antenna has a major surface having a facial surface area of greater than or equal to 1 nm² and less than or equal to 5,000 mm², or greater than or equal to 10 μm² and less than or equal to 100 μm²). Other ranges are also possible.

The antenna may, in certain embodiments, be in electrical communication with the plurality of interdigitated electrodes. Referring to FIG. 3, for example, antenna 118 and plurality of interdigitated electrodes 110 are in electrical communication via at least one interconnecting material 120, according to some embodiments. Interconnecting material 120 may be disposed between antenna 118 and single-crystalline material 106 and plurality of interdigitated electrodes over single crystalline material 106, in accordance with certain embodiments.

The interconnecting material may comprise any of a variety of suitable materials. In some embodiments, for example, the interconnecting material comprises an electrically conductive material, such as one or more metals, one or more conductive ceramics, and/or one or more conductive polymers. In certain embodiments, the interconnecting material comprises Ti, TiN, Au, Pt, Pd, Ni, NiNₓ, Cr, Al, Ag, Cu, Mo, Fe, Mg, Zn, and/or W. Other materials are also possible.

In some embodiments, at least a portion of the device may comprise one or more overlayers. Referring, for example, to FIG. 1B, device 100b may comprise overlayer 124, in accordance with certain embodiments.

The device may comprise any of a variety of suitable overlayers. In some embodiments, for example, the overlayer comprises a protective material. The protective material may be configured to protect one or more components of the device from physical and/or chemical damage that can damage and/or disconnect one or more electrical components of the device (e.g., the plurality of interdigitated electrodes, the antenna, the interconnecting material), in accordance with certain embodiments. In some embodiments, for example, the protective material may be configured to protect one or more components of the device from sweat, blood, saliva, tears, urine, and/or water.

In some embodiments, the protective material may be over at least a portion of the substrate, the single-crystalline material, the plurality of interdigitated electrodes, the antenna, and/or the interconnecting material. Suitable protective materials include, for example, a polyimide, a parylene, an epoxy, bisbenzocyclobutene (BCB), polyvinylidene fluoride (PVDF), polytetrafluoroethylene (PTFE), polyvinyl chloride (PVC), polystyrene (PS), polydimethylsiloxane (PDMS), styrene-ethylene-butylene-styrene block copolymer (SEBS), and the like. In certain embodiments, the protective material may comprise one or more auxetic holes that facilitate the exposure of the single-crystalline material to one or more stimuli (e.g., UV light, ions).

In certain embodiments, the overlayer comprises a stimuli detecting material. The stimuli detecting material may comprise an ion-selective membrane that is configured to trap (e.g., absorb) one or more ions, in accordance with certain embodiments. In some embodiments, for example, the ion-selective membrane is configured to trap sodium ions (Na⁺), potassium ions (K⁺), calcium ions (Ca²⁺), and/or the like. The stimuli detecting material (e.g., the ion-selective membrane) may be over at least a portion of the single-crystalline material and/or the plurality of interdigitated electrodes, according to some embodiments. The stimuli detecting material (e.g., the ion-selective membrane) may, in certain embodiments, comprise an ionophore, an ion-exchanger, a polymer, and/or a plasticizer. In some embodiments, for example, suitable stimuli detecting materials include, 4-tert-butylcalix[4]arene-tetraacetic acid tetraethyl ester; tetrakis[3,5-bis(trifluoromethyl)phenyl]borate (TFPB); poly(vinyl chloride) (PVC); bis(2-ethylhexyl) sebacate (DOS); valinomycin; and/or sodium tetraphenylborate (NaTPB).

In certain embodiments, the ion-selective membrane may be configured to trap (e.g., absorb) Na⁺ ions to the exclusion of all other possible ions. In some such embodiments, the stimuli-detecting material may comprise 4-tert-butylcalix[4]arene-tetraacetic acid tetraethyl ester, TFPB, PVC, and/or DOS.

In some embodiments, the ion-selective membrane may be configured to trap (e.g., absorb) K⁺ ions to the exclusion of all other possible ions. In some such embodiments, the stimuli-detecting material may comprise valinomycin, NaTPB, PVC, and/or DOS.

In some embodiments, a method of forming a device is described. FIG. 5 shows, according to certain embodiments, a method of forming a device.

In certain embodiments, the method comprises providing a two-dimensional (2D) material (e.g., graphene) positioned over a growth substrate and forming the single-crystalline material over the 2D material positioned over the growth substrate. See, for example, steps 250 and 252 in FIG. 5, in which single-crystalline material 106 is formed on 2D material 520 positioned over growth substrate 522, in accordance with certain embodiments. In some embodiments, the single-crystalline material is grown (e.g., epitaxially grown) on the 2D material. In certain embodiments, the epitaxial growth of the single-crystalline material on the 2D material may be performed by chemical vapor deposition (e.g., metal organic chemical vapor deposition), molecular beam epitaxy, and/or pulsed laser deposition.

The fabrication of single-crystalline materials on 2D materials (including fabrication via remote epitaxy methods) is further described in International Patent Application No. PCT/US2016/050701, filed Sep. 8, 2016, published as International Patent Application No. WO 2017/044577 on Mar. 16, 2017, and entitled “SYSTEMS AND METHODS FOR GRAPHENE BASED LAYER TRANSFER,” which is incorporated herein by reference in its entirety for all purposes.

The growth substrate may comprise any of a variety of suitable materials. In some embodiments, for example, the growth substrate comprises silicon, sapphire (e.g., aluminum oxide), STO, zinc oxide, magnesium aluminate, gadolinium gallium garnet, yttrium iron garnet, gadolinium scandate, lanthanum aluminate, barium titanate, lithium niobate, lithium tantalate, lead magnesium niobate-lead titanate, silicon carbide (SiC), a Ill-nitride material (e.g., GaN), and the like.

In some embodiments, the 2D material consists of a single monolayer of 2D material (e.g., a single monolayer of graphene). In other embodiments, multiple layers of 2D materials (e.g., multiple layers of graphene) can be used.

While the 2D material may be or comprise graphene (e.g., monolayer graphene or multilayer graphene), other types of 2D materials could also be used, as the disclosure is not meant to be limiting in this regard. In some embodiments, the 2D material comprises one or more transition metal dichalcogenide (TMD) monolayers, which are atomically thin materials of the type MX₂, with M being a transition metal atom (e.g., Mo, W, etc.) and X being a chalcogen atom (e.g., S, Se, or Te). In a TMD lattice, one layer of M atoms is usually sandwiched between two layers of X atoms. In another embodiment, the 2D material comprises boron nitride (e.g., hexagonal boron nitride). In yet another example, the 2D material can include a single-atom layer of metal, such as palladium and rhodium. Out of these 2D materials, graphene can have several desirable properties. For example, graphene is a crystalline film and is a suitable substrate for growing epitaxial over-layers. Second, graphene's weak interaction with other materials can substantially relax the lattice mismatching rule for epitaxial growth, potentially permitting the growth of most semiconducting films with low defect densities. Third, epilayers grown on a graphene substrate can be easily and precisely released from the substrate owing to graphene's weak van der Waals interactions, thereby allowing rapid mechanical release of epilayers without post-release reconditioning of the released surface. Fourth, graphene's mechanical robustness can increase or maximize its reusability for multiple growth/release cycles.

In certain embodiments, the method comprises transferring the single-crystalline material from the growth substrate to a receiving substrate. The single-crystalline material may be transferred from the growth substrate to the receiving substrate, in some embodiments, by removing (e.g., exfoliating) the single-crystalline material from the 2D material positioned over the growth substrate. In certain embodiments, the 2D material can be used as a release layer. The single-crystalline material may, in some embodiments, be removed from the 2D material positioned over the growth substrate using a transfer substrate (e.g., a stressor and/or handler). Referring to step 254 in FIG. 5, for example, single-crystalline material 106 is removed from 2D material 520 positioned over growth substrate 522 using transfer substrate 524, in accordance with certain embodiments.

The transfer substrate may be a metal stressor, in some embodiments. In some such embodiments, the transfer substrate may be used to peel the single-crystalline material from the 2D material positioned over the growth substrate under an internal stress of greater than or equal to 100 MPa and less than or equal to 1 GPa.

In certain embodiments, after removal of single-crystalline material 106 using transfer substrate 524, 2D material 520 and growth substrate 522 may be recycled and reused to grow (e.g., epitaxially grow) a subsequent single-crystalline material, thereby reducing overall fabrication and processing costs.

In certain embodiments, the single-crystalline material may be transferred to the receiving substrate such that at least a portion of the single-crystalline material is positioned over a cavity of the receiving substrate. Referring to step 258 in FIG. 5, for example, single-crystalline material 106 may, in some embodiments, be transferred to receiving substrate 102 such that at least a portion of single-crystalline material 106 is positioned over cavity 104 of substrate 102, thereby providing device 100 in step 260 after removal of transfer substrate 524.

The receiving substrate may comprise any of a variety of suitable materials, including those described above with respect to the substrate of the device (i.e., a polyimide and/or PDMS).

According to some embodiments, after the transferring, the single-crystalline material is or is part of a freestanding layer and has a thickness of less than or equal to 300 nm, as described above. In some embodiments, for example, the single-crystalline material that is or is part of the freestanding layer may be positioned and/or aligned over one or more through-holes extending from the first surface of the receiving substrate to the second surface of the receiving substrate that is opposite the first surface.

At least a portion of the single-crystalline material may be associated with (e.g., bound to) the receiving substrate via an epoxy, according to certain embodiments. In certain embodiments, for example, the single-crystalline material may be bound to the receiving substrate along some or all of its edges, with at least a portion of the surface of the single-crystalline material over the receiving substrate being free of contact with the receiving substrate or any other solid material.

In certain embodiments, the method comprises forming one or more interdigitated electrodes. In some embodiments, for example, one or more electrically conductive materials (e.g., NiNₓ and/or Au) may be deposited on a portion of the device (e.g., on the single-crystalline material). In some embodiments, depositing the interdigitated electrode materials may comprise sputtering and/or physical vapor deposition (e.g., electron-beam evaporation). According to certain embodiments, a photoresist may be used in conjunction with the deposition of the electrically conductive interdigitated electrode materials to form a patterned plurality of interdigitated electrodes.

In some embodiments, the method comprises forming an antenna. In certain embodiments, for example, one or more electrically conductive materials (e.g., Ti and/or Au) may be deposited on a portion of the device (e.g., on the substrate). In some embodiments, depositing the electrically conductive antenna materials may comprise physical vapor deposition (e.g., electron-beam evaporation). According to certain embodiments, a photoresist may be used in conjunction with the deposition of the electrically conductive antenna materials to form the antenna.

In certain embodiments, the method comprises forming an interconnecting material. In certain embodiments, for example, one or more electrically conductive materials (e.g., Ti and/or Au) may be deposited on a portion of the device (e.g., on the substrate). In some embodiments, depositing the electrically conductive interconnecting materials may comprise physical vapor deposition (e.g., electron-beam evaporation). According to certain embodiments, a photoresist may be used in conjunction with the deposition of the electrically conductive interconnecting materials to form the interconnecting material.

In some embodiments, the method comprises forming an overlayer (e.g., a protective material, a stimuli detecting material). In certain embodiments, for example, one or more protective materials (e.g., a polyimide) and/or stimuli detecting materials (e.g., an ion-selective membrane) may be deposited on a portion of the device. In some embodiments, for example, the protective material may be deposited on at least a portion of the substrate, the single-crystalline material, the interdigitated electrodes, the antenna, and/or the interconnecting material. In certain embodiments, the stimuli detecting material may be deposited on at least a portion of the single-crystalline material and/or the interdigitated electrodes. In certain embodiments, depositing the overlayer may comprise spin coating.

In certain embodiments, the method comprises forming one or more auxetic holes through the substrate and/or the overlayer (e.g., the protective material, the stimuli detecting material). According to some embodiments, for example, one or more auxetic holes may be formed through the substrate and/or the overlayer using a photoresist and an etching process.

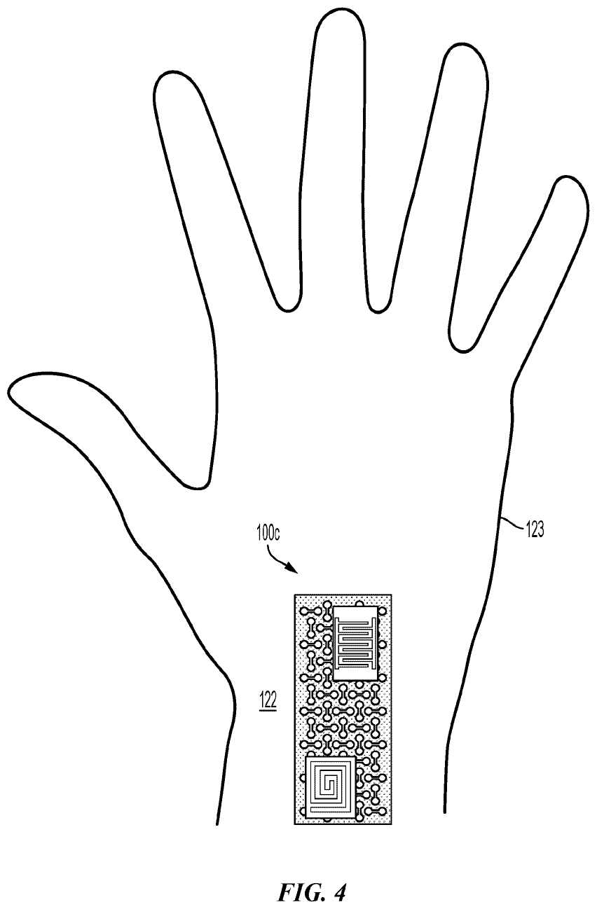

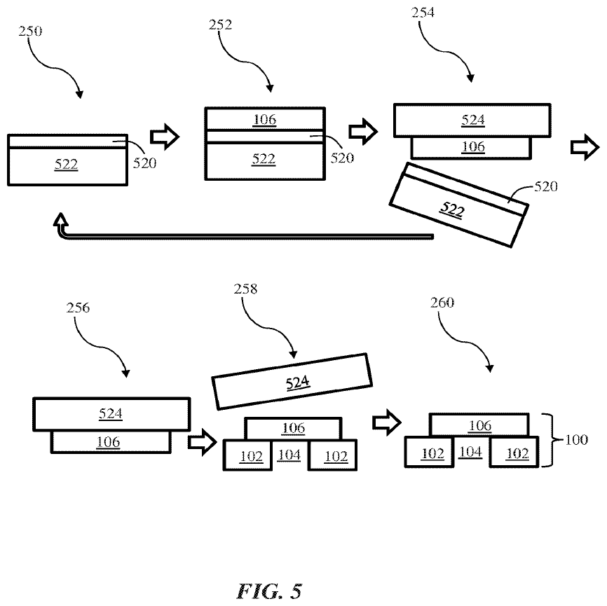

According to some embodiments, the device may be positioned over a portion of skin of a user. FIG. 4 shows, according to certain embodiments, a top-view schematic diagram of device 100c positioned over portion of skin 122 of user 123. The device may be positioned over any of a variety of suitable portions of skin, including, for example, a portion of skin on a hand, an arm, a foot, a leg, a neck, and/or any other suitable location.

The device may be positioned over a portion of skin of a user for any of a variety of suitable durations. In some embodiments, for example, the device is configured to be positioned over the portion of skin of the user for at least 30 minutes, at least 1 hour, at least 6 hours, at least 1 day, at least 2 day, at least 3 days, at least 4 days, at least 5 days, at least 6 days, at least 1 week, at least 2 weeks, at least 3 weeks, or at least 1 month. In certain embodiments, the device is configured to be positioned over the portion of skin of the user for less than or equal to 6 months, less than or equal to 1 month, less than or equal to 3 weeks, less than or equal to 2 weeks, less than or equal to 1 week, less than or equal to 6 days, less than or equal to 5 days, less than or equal to 4 days, less than or equal to 3 days, or less than or equal to 2 days. Combinations of the above recited ranges are possible (e.g., the device can be configured to be positioned over the portion of skin of the user for at least 30 minutes and less than or equal to 6 months, or for at least one week and less than or equal to two weeks). Other ranges are also possible.

In some embodiments, the device may be applied over the portion of skin of the user, removed from the portion of skin of the user, and reapplied to the portion of skin of the user (or, in some embodiments, reapplied to a different portion of skin of the user).

According to certain embodiments, a method of operating a device (e.g., a resonator) is described. In some embodiments, for example, the device is a resonator (e.g., a surface acoustic wave resonator) comprising a single-crystalline material having a thickness of less than or equal to 300 nm that is or is part of a freestanding layer, as described herein.

In some embodiments, the method comprises applying an electrical potential to the device (e.g., surface acoustic wave resonator). According to certain embodiments, and as would generally be understood by a person of ordinary skill in the art, the application of an electrical potential to the device results in the single-crystalline material serving as a resonator (e.g., a piezoelectric resonator) that generates a mechanical wave (e.g., a surface acoustic wave). In some embodiments, for example, the plurality of interdigitated electrodes delivers electrical energy from the antenna to the single-crystalline material, which converts the input electrical signal into a mechanical wave (e.g., a surface acoustic wave). The electrical potential may be applied to the device via any of a variety of suitable means, including, but not limited to, an external source (e.g., a wireless reader) that initiates EM waves, in accordance with certain embodiments.

In certain embodiments, the method comprises determining a change in a resonant frequency of the single-crystalline material in response to an environmental change. In some embodiments, for example, the resonant frequency of the mechanical wave generated by the single-crystalline material may be sensitive to a number of stimuli, such as, for example, mechanical strain, light exposure, and/or mass changes. In certain embodiments, the one or more stimuli resulting from an environmental change surrounding the device may alter the resonant frequency of the mechanical wave. In some embodiments, the mechanical wave is converted back into an electrical signal that is retransmitted back to the antenna. The electrical signal may, in some embodiments, be measured by the external source (e.g., wireless reader), therefore yielding information about the environmental change resulting from the mechanical, optical, and biochemical stimuli.

In certain embodiments, the device (e.g., resonator) is configured to detect a strain (e.g., a tensile strain). According to some embodiments, for example, the device may be configured such that resonant frequency shifts in the mechanical wave (e.g., surface acoustic wave) produced by the single-crystalline material resulting from a mechanical strain may be detected as an electrical signal by the antenna. In some embodiments, the device is configured to measure strain resulting from an arterial pulse wave and/or strain resulting from one or more bending cycles of the device.

The minimum detectable strain (e.g., tensile strain) of the device may be any of a variety of suitable values. In some embodiments, for example, the device has a minimum detectable tensile strain of less than or equal to 0.1%, less than or equal to 0.09%, less than or equal to 0.08%, less than or equal to 0.07%, less than or equal to 0.06%, less than or equal to 0.05%, less than or equal to 0.04%, less than or equal to 0.03%, less than or equal to 0.02%, less than or equal to 0.01%, less than or equal to 0.001%, or less, at an energy consumption less than or equal to 8×10⁻⁸ Joules per measurement. In certain embodiments, the device has a minimum detectable tensile strain of greater than or equal to 0.0001%, greater than or equal to 0.001%, greater than or equal to 0.01%, greater than or equal to 0.02%, greater than or equal to 0.03%, greater than or equal to 0.04%, greater than or equal to 0.05%, greater than or equal to 0.06%, greater than or equal to 0.07%, greater than or equal to 0.08%, or greater than or equal to 0.09% at an energy consumption less than or equal to 8×10⁻⁸ Joules per measurement. Combinations of the above recited ranges are also possible (e.g., the device has a minimum detectable tensile strain of greater than or equal to 0.0001% and less than or equal to 0.1% at an energy consumption less than or equal to 8×10⁻⁸ Joules per measurement, or greater than or equal to 0.04% and less than or equal to 0.06% at an energy consumption less than or equal to 8×10⁻⁸ Joules per measurement). Other ranges are also possible.

The maximum detectable strain (e.g., tensile strain) of the device may be any of a variety of suitable values. In some embodiments, for example, the device has a maximum detectable tensile strain of less than or equal to 1000%, less than or equal to 100%, less than or equal to 50%, less than or equal to 25%, less than or equal to 20%, less than or equal to 19%, less than or equal to 18%, less than or equal to 17%, or less than or equal to 16%, less than or equal to 15%, less than or equal to 10%, or less, at an energy consumption less than or equal to 8×10⁻⁸ Joules per measurement. In certain embodiments, the device has a maximum detectable tensile strain of greater than or equal to 1%, greater than or equal to 10%, greater than or equal to 15%, greater than or equal to 16%, greater than or equal to 17%, greater than or equal to 18%, greater than or equal to 19%, greater than or equal to 20%, greater than or equal to 25%, greater than or equal to 50%, greater than or equal to 100%, or greater, at an energy consumption less than or equal to 8×10⁻⁸ Joules per measurement. Combinations of the above recited ranges are also possible (e.g., the device has a maximum detectable tensile strain of greater than or equal to 1% and less than or equal to 1000% at an energy consumption less than or equal to 8×10⁻⁸ Joules per measurement, or greater than or equal to 16% and less than or equal to 17% at an energy consumption less than or equal to 8×10⁻⁸ Joules per measurement). Other ranges are also possible.

According to certain embodiments, the minimum detectable strain and/or the maximum detectable strain of the device may be determined by providing a flexible test substrate with known modulus and known thickness, disposing the device on the test substrate, applying a known bending radius, and calculating the strain (e.g., tensile strain).

The device may be configured to withstand any of a variety of suitable bending cycles without a fracture. In certain embodiments, for example, the device is configured to withstand greater than or equal to 500 bending cycles, greater than or equal to 1,000 bending cycles, greater than or equal to 5,000 bending cycles, greater than or equal to 10,000 bending cycles, greater than or equal to 50,000 bending cycles, or greater than or equal to 100,000 bending cycles without a fracture. In some embodiments, the device is configured to withstand less than or equal to 1,000,000 bending cycles, less than or equal to 100,000 bending cycles, less than or equal to 50,000 bending cycles, less than or equal to 10,000 bending cycles, less than or equal to 5,000 bending cycles, or less than or equal to 1,000 bending cycles without a fracture. Combinations of the above recited ranges are possible (e.g., the device is configured to withstand greater than or equal to 500 bending cycles and less than or equal to 1,000,000 bending cycles without a fracture, or greater than or equal to 1,000 bending cycles and less than or equal to 5,000 bending cycles without a fracture). Other ranges are also possible.

According to certain embodiments, the bending cycles of the device may be determined by providing a flexible test substrate with known modulus and known thickness, disposing the device on the test substrate, applying a known bending radius, calculating the strain (e.g., tensile strain), and repeating the bending cycles. Each bending cycle can comprise starting with the device in a no strain state, bending the device to a known bending radius and/or the maximum detectible strain of the device, and returning the device to a no strain state.

In certain embodiments, the device (e.g., resonator) is configured to detect light. In some embodiments, for example, the device is configured to detect UV light. According to some embodiments, the device may be configured such that resonant frequency shifts in the mechanical wave (e.g., surface acoustic wave) produced by the single-crystalline material resulting from exposure to UV light may be detected as an electrical signal by the antenna.

The detectable UV light intensity of the device may be any of a variety of suitable values. In some embodiments, for example, the device has a detectable UV light intensity of greater than or equal to 0.0001 mW/cm², greater than or equal to 0.001 mW/cm², greater than or equal to 0.01 mW/cm², greater than or equal to 0.1 mW/cm², greater than or equal to 1 mW/cm², greater than or equal to 10 mW/cm², greater than or equal to 100 mW/cm², or greater than or equal to 1,000 mW/cm². In certain embodiments, the device has a detectable UV light intensity of less than or equal to 10,000 mW/cm², less than or equal to 1,000 mW/cm², less than or equal to 100 mW/cm², less than or equal to 10 mW/cm², less than or equal to 1 mW/cm², less than or equal to 0.01 mW/cm², or less than or equal to 0.001 mW/cm². Combinations of the above recited ranges are also possible (e.g., the device has a detectable UV light intensity of greater than or equal to 0.0001 mW/cm² and less than or equal to 10,000 mW/cm², or greater than or equal to 0.01 mW/cm² and less than or equal to 1 mW/cm²). Other ranges are also possible.

In certain embodiments, the UV responsivity is measured by exposing the device to UV light of varying intensities using, for example, a UV conformal photocurrent microscopy (UVCPM) system, and recording the output signals of the device using a vector network analyzer (VNA).

According to some embodiments, the device (e.g., resonator) is configured to detect chemical concentrations. In certain embodiments, for example, the device is configured to measure ion concentrations (e.g., Na⁺, K⁺ and/or Ca²⁺ concentrations). As explained above, in accordance with certain embodiments, a stimuli detecting material, such as an ion-selective membrane that is configured to trap ions and undergo changes in mass, may be positioned over at least a portion of the device (e.g., the single-crystalline material, the plurality of interdigitated electrodes). In some such embodiments, the device may be configured such that resonant frequency shifts in the mechanical wave (e.g., surface acoustic wave) produced by the single-crystalline material resulting from changes in the concentration of ions trapped in the ion-selective membrane may be detected as an electrical signal by the antenna.

The detectable ion concentration of the device may be any of a variety of suitable values. In certain embodiments, for example, the device is configured to detect an ion concentration greater than or equal to 0.5 mM, greater than or equal to 1 mM, greater than or equal to 2 mM, greater than or equal to 5 mM, greater than or equal to 10 mM, greater than or equal to 20 mM, or greater than or equal to 50 mM. In some embodiments, the device is configured to detect an ion concentration less than or equal to 100 mM, less than or equal to 50 mM, less than or equal to 20 mM, less than or equal to 10 mM, less than or equal to 5 mM, less than or equal to 2 mM, or less than or equal to 1 mM. Combinations of the above recited ranges are also possible (e.g., the device is configured to detect an ion concentration greater than or equal to 0.5 mM and less than or equal to 100 mM, or greater than or equal to 2 mM and less than or equal to 5 mM). Other ranges are also possible.

In certain embodiments, the ion concentration detected by the device is measured by exposing the device to ion-containing solutions (e.g., solutions of NaCl) comprising varying concentrations of ions using a peristaltic pump at a consistent flow rate, and recording the output signals of the device using a VNA.

### EXAMPLE

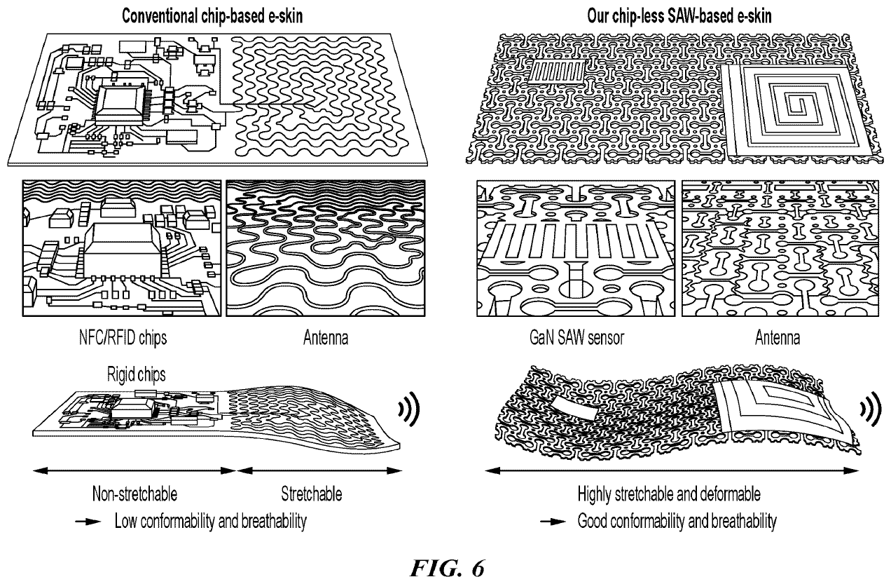

The following example describes a chip-less wireless e-skin-based health monitoring sensor device based on a surface acoustic wave resonator. The device achieves marked improvements in strain sensitivity, versatility, power efficiency, and long-term wearability compared to conventional e-skin sensors. The improvements are permitted by integrating ultrathin, single-crystalline, freestanding membranes of gallium nitride (GaN) as a material for sensing and wireless communication (FIG. 6). The GaN-based e-skin device exhibits excellent sensing performance for a broad range of external stimuli with low power consumption, owing to its excellent piezoelectric/optoelectronic/electronic properties together with biocompatibility.

Remote homoepitaxy of GaN on graphene-coated GaN substrates allowed buffer-free growth of ultrathin GaN epitaxial layers, which were easily released from weak graphene-GaN interfaces by a 2D material-based layer transfer (2DLT) process. The freestanding GaN nanomembranes (˜200 nm) produced SAWs with electromechanical coefficients higher than those of SAWs produced by thicker, non-freestanding counterparts. Stretchable and highly sensitive SAW-based e-skin sensor devices that are configured to wirelessly detect strain, chemical concentrations, and UV light without having any wireless chips were fabricated. In addition, the GaN nanomembrane was integrated on ultrathin PDMS patches (˜20 μm) containing dense arrays of perforations that allow removal of sweat and skin byproducts, thereby providing for long term health monitoring for more than 1 week.

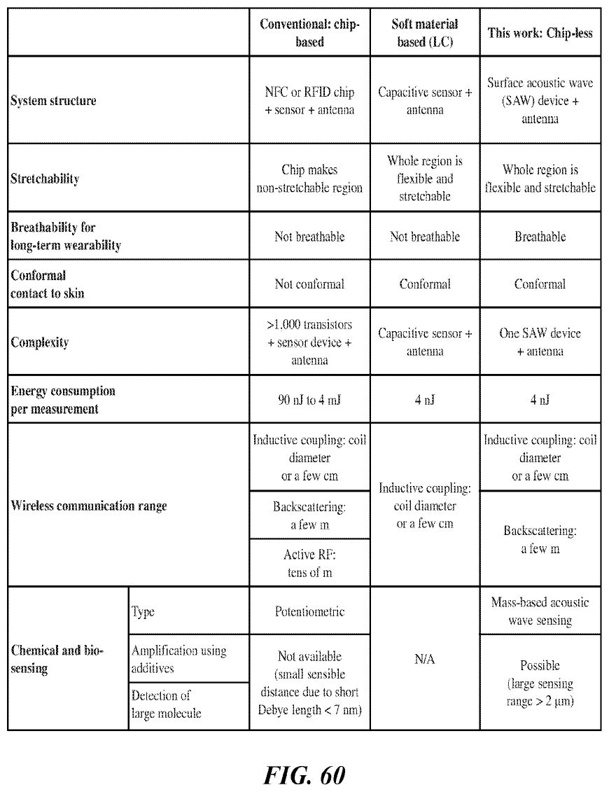

FIG. 6 shows the schematic comparison between conventional chip-based wireless e-skin systems and the SAW-based chip-less wireless e-skin device (see FIG. 60 for detailed comparison). To construct conventional chip-based wireless e-skin systems, integrated circuit chips such as NFC or RFID chips as well as other circuit elements such as diodes, resistors, and capacitors are integrated on flexible silicone patches and electrically connected to sensors and a RF antenna. The wireless chips collect signals from the sensors, convert them into a digital signal, and send the digital signals through the antenna wirelessly. Such chips, denoted as black blocks in the schematics of FIG. 6, are too thick and rigid to enable completely conformal lamination on the skin of a user, and thus compromise the overall stretchability of the device. In addition, thick silicone elastomers (e.g., 300-500 μm) required for chip integration can disturb skin barrier function over time due to sweat-impermeability and occlusion. Moreover, the chip-containing devices require substantial power to operate.

In the chip-less wireless e-skin device described herein, an ultrathin GaN SAW sensor replaces the bulky chip and circuit components used in conventional chip-based wireless e-skin systems. The SAW sensor is made of a rectangular slab of a GaN nanomembrane (size: 408 μm×640 μm, thickness: ˜200 nm) integrated onto a silicone patch. Patterns of inter-digitated metal electrodes (NiNₓ/Au˜20/20 nm) deliver electrical energy from the antenna (Ti/Au˜2/100 nm) into the GaN nanomembrane, which serves as a piezoelectric resonator that converts the input electrical signal into a mechanical wave. This is a unique advantage of GaN-based e-skin devices over the more conventional Si-based e-skins systems, which lack piezoelectric properties. The SAW is sensitive to mechanical strain, UV exposure (via optical absorption by GaN), and mass changes (via absorption and desorption of ions in coatings on top). The SAW is converted back into an electrical signal and transmitted through the antenna, and changes in resonant frequency yields information about the mechanical, optical, and biochemical stimuli detected by the SAW sensor. Because the functional GaN and metal layers are all ultrathin, the silicone elastomer can also be much thinner (˜20 μm) than those used in chip-based e-skin systems, therefore improving the softness, skin-conformability, and long-term wearability of the chip-less wireless SAW-based e-skin device. In addition, the SAW devices consume significantly less power compared to the wireless chip systems, which need to support power for thousands of transistors and other circuit components. The low power consumption of the SAW-based e-skin device also has the potential to increase communication distances compared to other battery-less e-skin systems based on wireless chips.

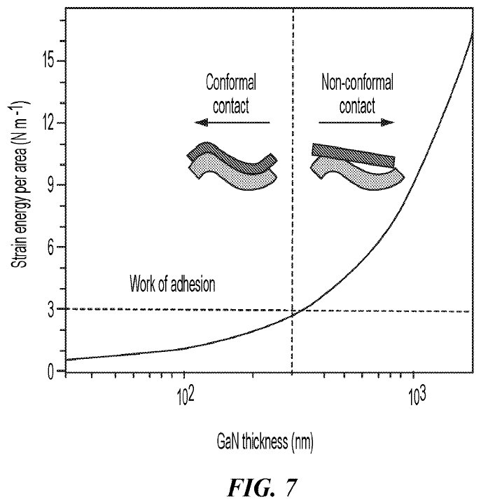

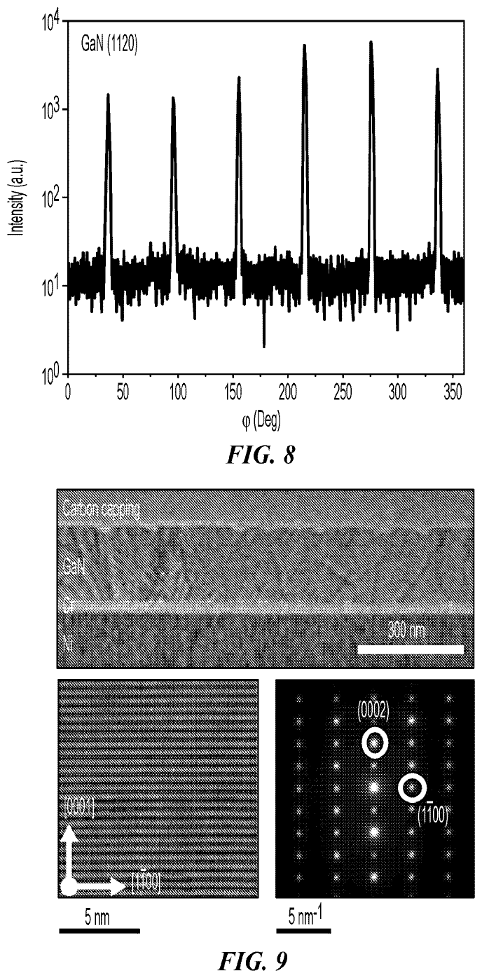

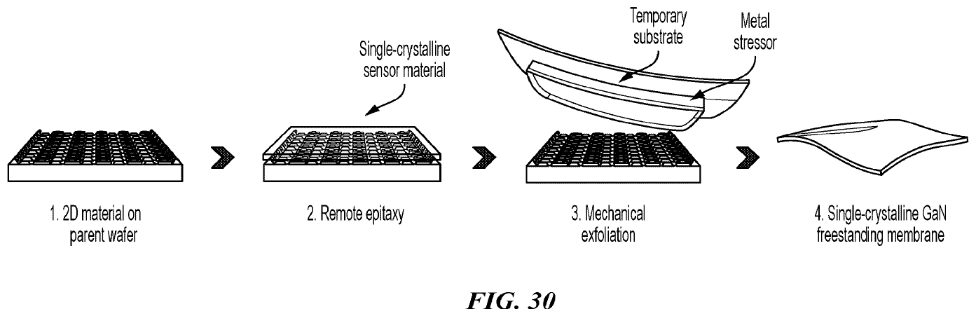

Traditional wireless SAW sensors have relied on thick, non-freestanding GaN films that are tethered to a wafer, which are difficult to integrate into flexible e-skin systems. The single-crystalline GaN film, produced via remote epitaxy and 2DLT, achieves thickness and flexibility that allows for conformal adhesion on human skin. The required GaN thicknesses for conformal skin adhesion was estimated by simulating the correlation between built-in strain energy per area and GaN thickness (FIG. 7). The critical GaN film thickness, at which the strain energy within the film exceeds the work of adhesion, is estimated to be 300 nm, indicating that the GaN piezoelectric resonator must be thinner than this to yield skin-conformity. Remote epitaxy was found to yield single-crystalline GaN membranes with such thickness, directly seeding growth from the substrate and producing ultrathin epitaxial membranes that could be released from the 2D materials on the substrate. This process also allowed for the reduction in material costs for GaN films by allowing re-use of the costly epitaxial substrate via simple oxygen plasma etching process followed by growth of another 2D layer. Remote epitaxy of 200 nm-thick GaN membranes on graphene-coated GaN substrates, followed by the exfoliation of the GaN membranes via 2DLT was performed (FIG. 30). The HRXRD phi scan data in FIG. 8 shows the perfect single-crystallinity of GaN on graphene. FIG. 9 shows a cross-sectional TEM image and an associated selective-area diffraction image of a 200 nm-thick GaN membrane that was precisely separated from the graphene on a mother substrate and suspended on a metallic mechanical support. The GaN nanomembrane shows uniquely oriented atomic planes. Additionally, the GaN surface is atomically flat as shown by atomic force microscopy (AFM) analysis. These properties are important for providing high-performance electromechanical and optoelectronic devices.

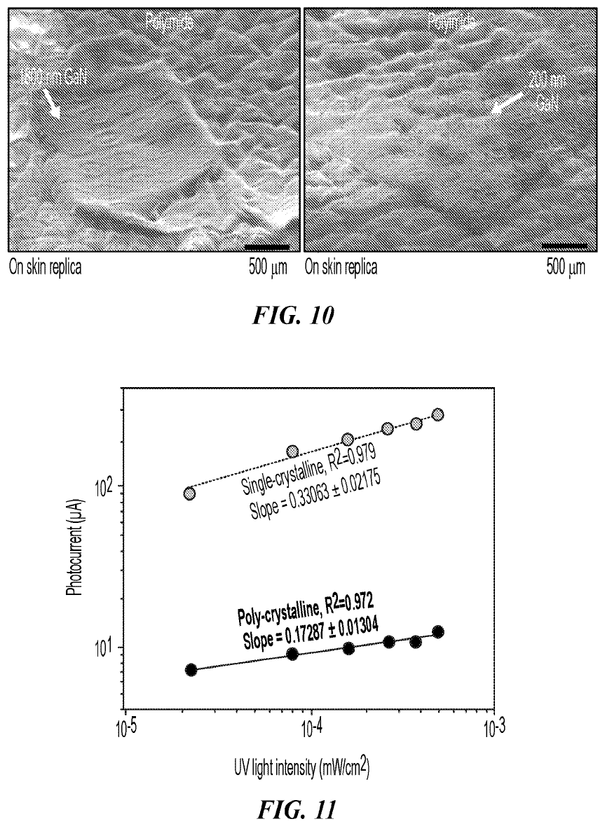

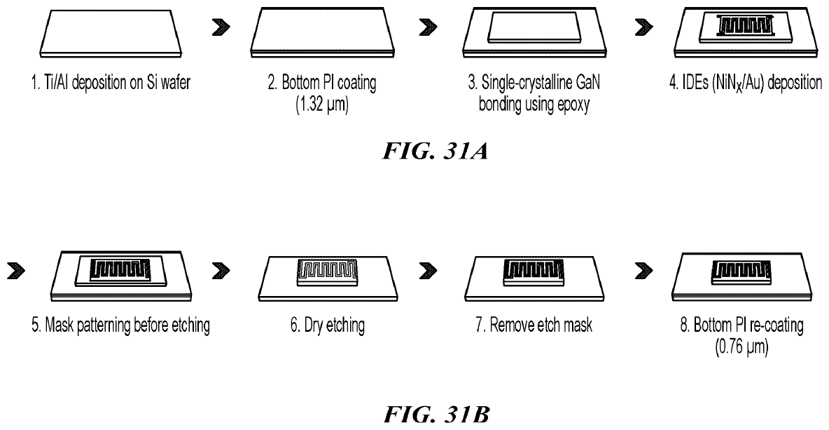

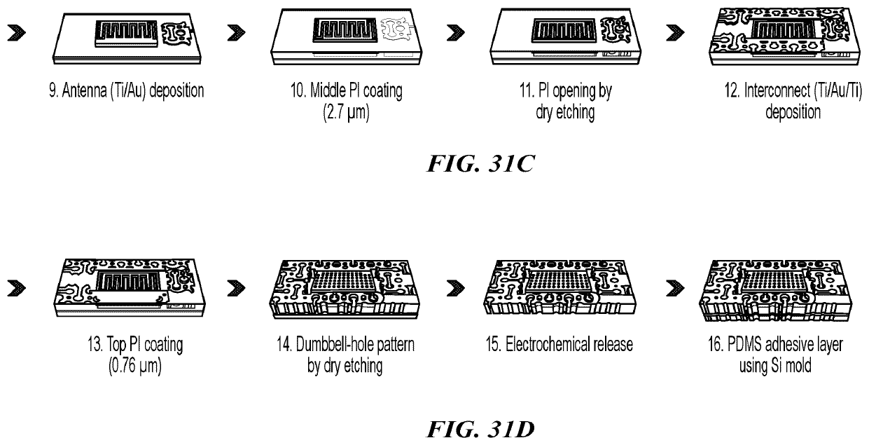

The capability of the single-crystalline GaN membranes to laminate conformally on skin was verified experimentally by attaching the membranes on skin replica samples made of Ecoflex silicone. The left SEM image in FIG. 10 illustrates a 1.8 μm-thick GaN film that appears relatively flat, unable to bend/adhere to the microscale features on skin replica. In contrast, the surface morphology of a 200 nm-thick GaN film (right SEM image in FIG. 10) follows the small pits and curvatures on the skin replica sample. Additionally, to achieve long-term wearability and user imperceptibility, the ultrathin GaN membranes were integrated on auxetic dumbbell hole-patterned PDMS that serves as the skin-attachable patch for the e-skin device (FIGS. 31A-31D). The patch is effective in managing the strain from the movement of skin, and exhibits excellent mechanical compatibility between the patch and inorganic membranes, which prevents causing mechanical damage to brittle inorganic devices and enables long-term wearability. The full process flow for fabricating the single-crystalline GaN e-skin device is depicted in FIGS. 30, 31A-31D, 32A-32B, 33A-33C, and 34.

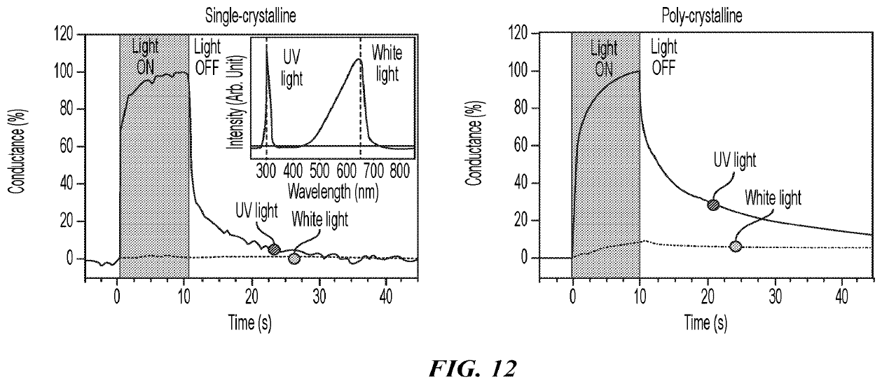

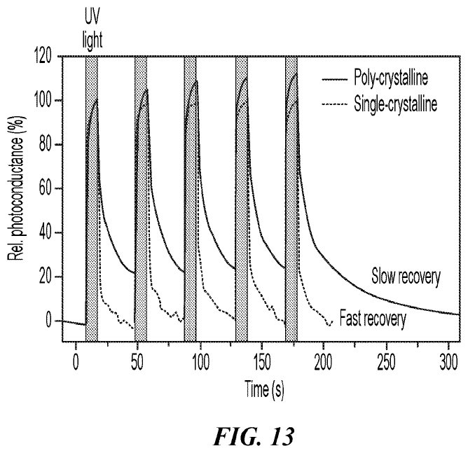

To understand the optoelectronic performances of the GaN nanomembranes, GaN-metal Schottky junction diodes were fabricated using 200 nm-thick membranes of both single-crystalline GaN, obtained via remote epitaxy and 2DLT, and poly-crystalline GaN, which is widely available via sputtering techniques, and their sensitivities to UV light were compared. UV radiation is the primary driver of skin cancers and thus represents an important tracking target for e-skin health monitoring devices. It is also a unique application area for SAW-based e-skin devices, because existing chip-less wireless e-skin systems based on LC resonators lack semiconductor components to detect light, and the indirect band gap of GaN allows significantly higher photosensitivity compared to Si-based photodetectors. FIG. 11 shows the recorded photocurrents of GaN diodes on e-skin to exposures of UV light at varying intensities. The results indicate a UV responsivity of 10.06 A W⁻¹ at 15.90 mW/cm² for the single-crystalline GaN diode, which is 37-fold higher than that of the polycrystalline GaN diode. The UV responsivity is also higher than those reported for e-skin sensors based on polycrystalline inorganic materials or single-crystalline Si, which has poor optical absorption in the UV wavelength regimes, and is comparable to that of the state-of-the art single-crystalline GaN UV sensors on “rigid” wafers. The single-crystalline GaN diode also exhibits UV sensing speed/recovery time and selectivity (to UV light over white light) higher than those of polycrystalline GaN diode, as illustrated in FIGS. 12 and 13.

The excellent piezoelectricity and perfect single-crystallinity of the ultrathin GaN film enhances the degree to which the device provides wireless communication without using NFC/RFID chips. The chip-less wireless e-skin device was created by developing the formation of highly sensitive SAWs on ultrathin single-crystalline GaN freestanding membranes; and developing the freestanding SAW device as a biosensing platform. Upon successful lamination on the human body, the e-skin device generates a SAW that responds sensitively to physiological activities, the changes of which are detected wirelessly through the antenna. It has been previously reported that SAW generated by ultrathin GaN films grown on a sapphire or SiC substrate is negligible due to the strong binding of the film to substrate. The free standing, highly crystalline GaN films that have been declamped from the substrate, however, generate SAWs with a greatly enhanced electromechanical coupling value.

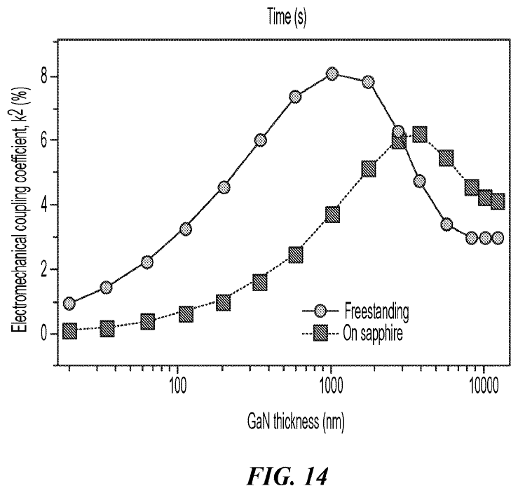

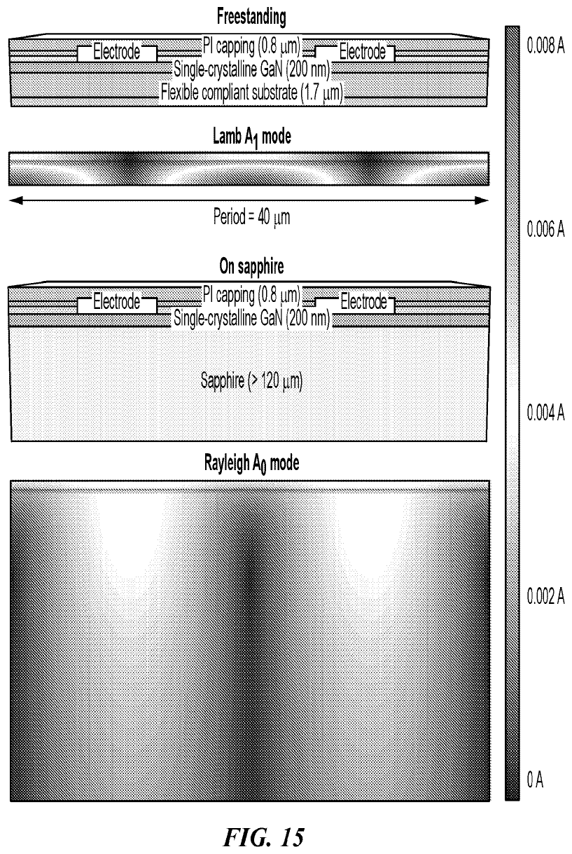

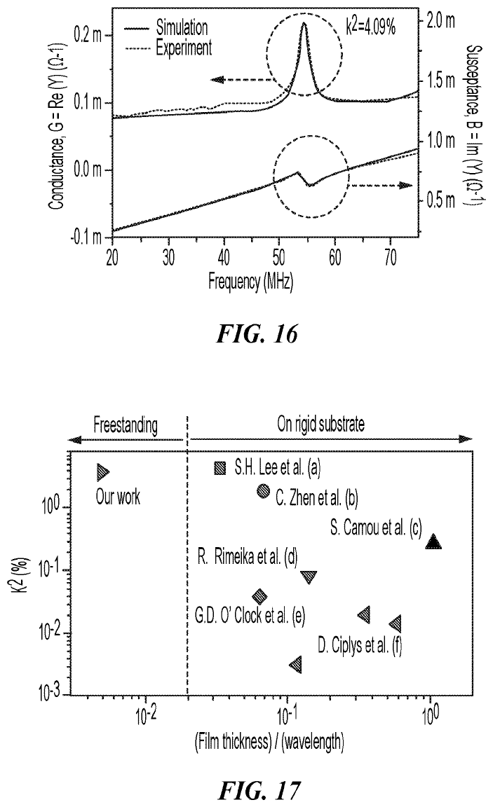

The simulation of SAW generation in GaN (FIGS. 14 and 15) showed that the electromechanical coupling coefficient k² is negligible for substrate-bound GaN films that are thinner than 300 nm. Without wishing to be bound by any particular theory, it is believed that this is because substrate binding alters the acoustic mode and substantially reduces the displacement amplitude of acoustic vibration. However, declamping of GaN from the substrate substantially enhances electromechanical coupling by eliminating the binding effect. The k² of the freestanding 200 nm-thick GaN obtained by 2DLT was experimentally confirmed to be close to the value of 4.09% (FIG. 16) for 2.0 μm-thick GaN SAW sensor on sapphire substrate. As shown in the benchmark plot in FIG. 17, the GaN film's k² value is on par with values previously achieved by epitaxial GaN SAW sensors with greater thicknesses bound on sapphire wafers. A high k² value is important for wireless detection as it increases the signal-to-noise ratio in the resonant frequency shift of the SAW device on the human skin.

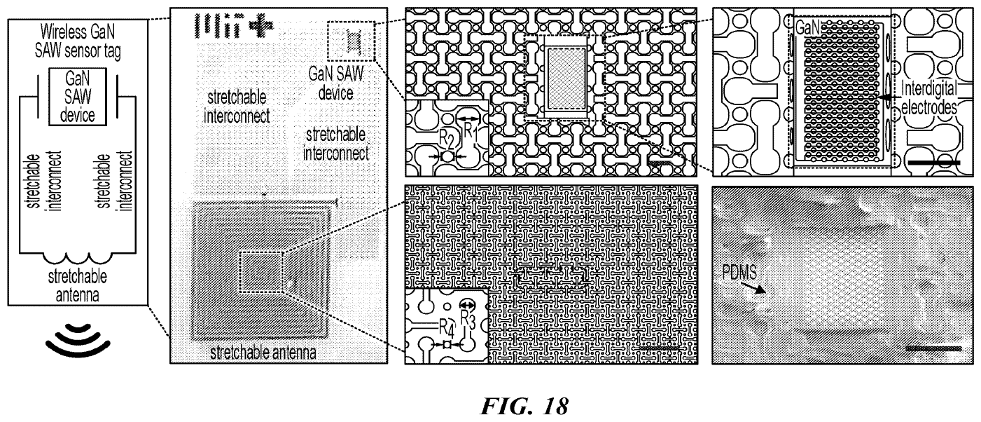

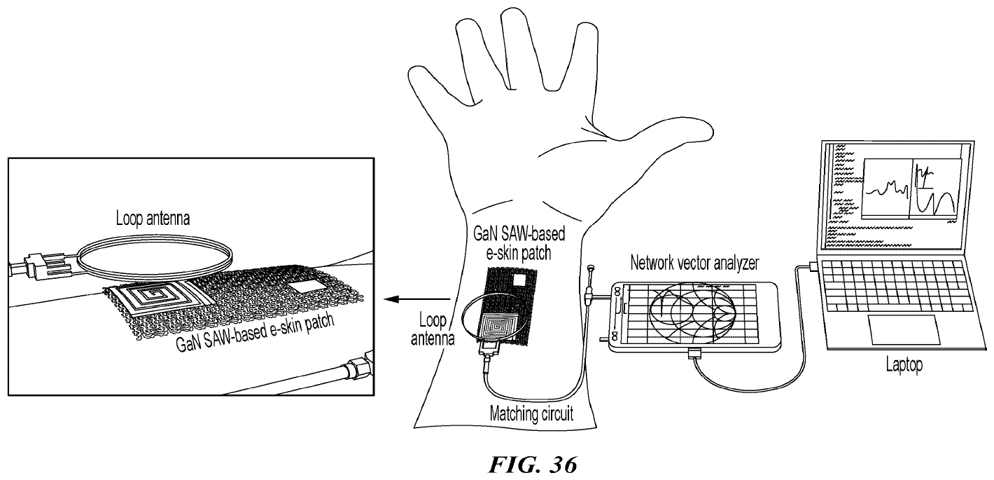

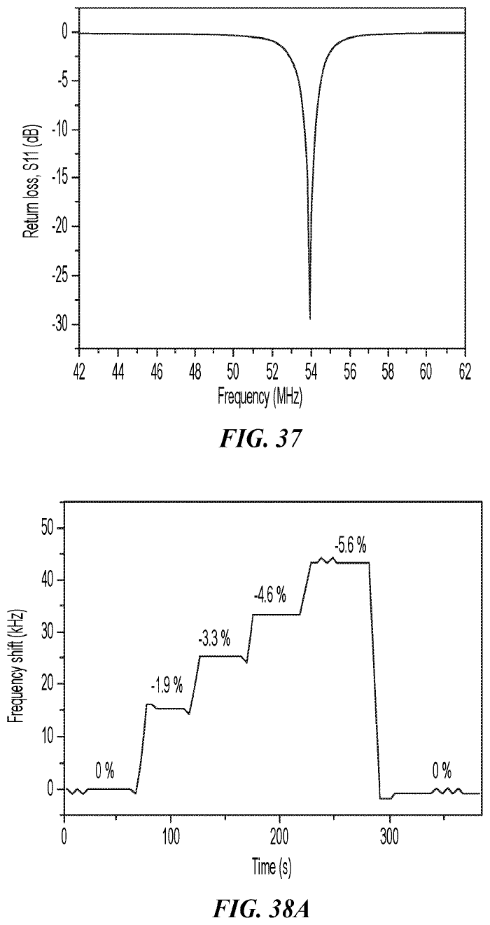

FIG. 18 shows a schematic illustration and microscopy images of the chip-less wireless e-skin device. To increase sensitivity, the e-skin device was designed such that the sensing regions of SAW devices on PDMS skin patch are freestanding and suspended in air. This was achieved by transferring SAW devices onto the PDMS patch such that the devices are aligned on top of the holes that penetrate through the patch. The freestanding SAW devices are connected via stretchable interconnects to the stretchable antenna. Dumbbell holes patterned throughout the patch ensure stretchability, conformability, and breathability of the e-skin device. When an external wireless reader initiates electromagnetic (EM) waves, the stretchable antenna converts them into electrical signals, which then generates acoustic waves in the piezoelectric GaN SAW device on the e-skin device (FIG. 36). By scanning the return loss (S₁₁) over a range of frequencies using the external wireless reader, the resonant frequency of GaN SAW (53.95 MHz) was recorded wirelessly (FIG. 37).

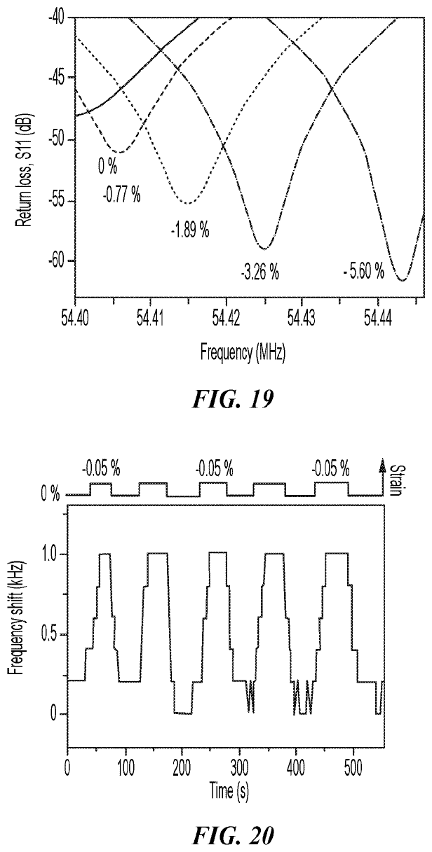

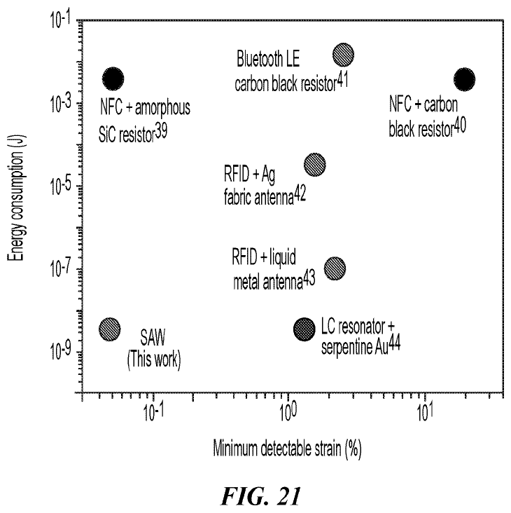

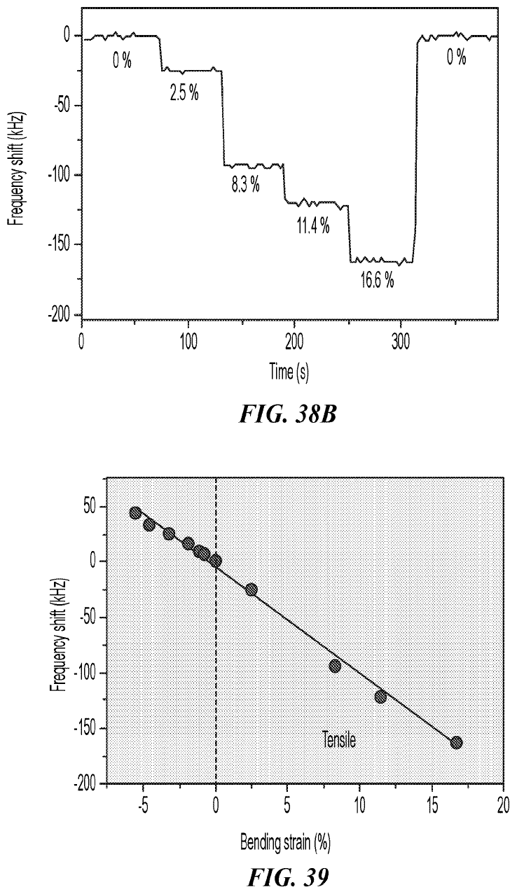

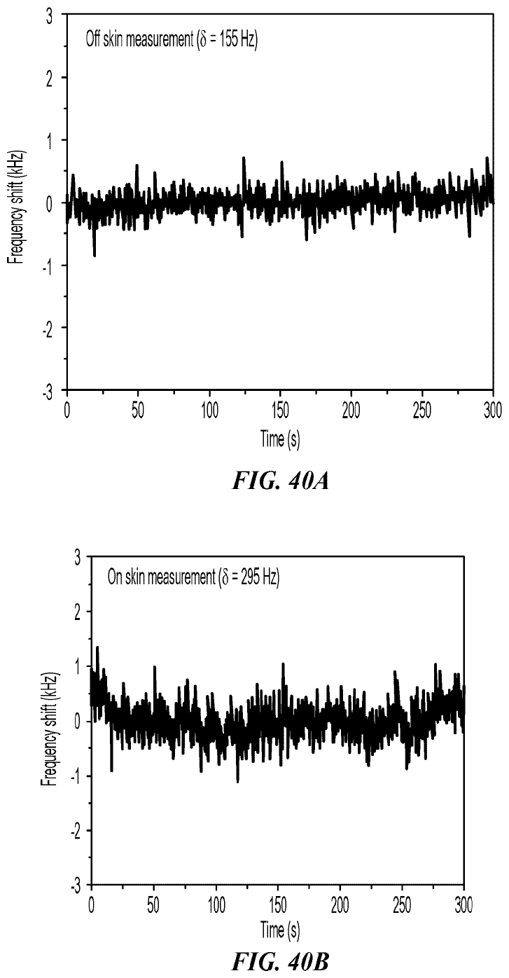

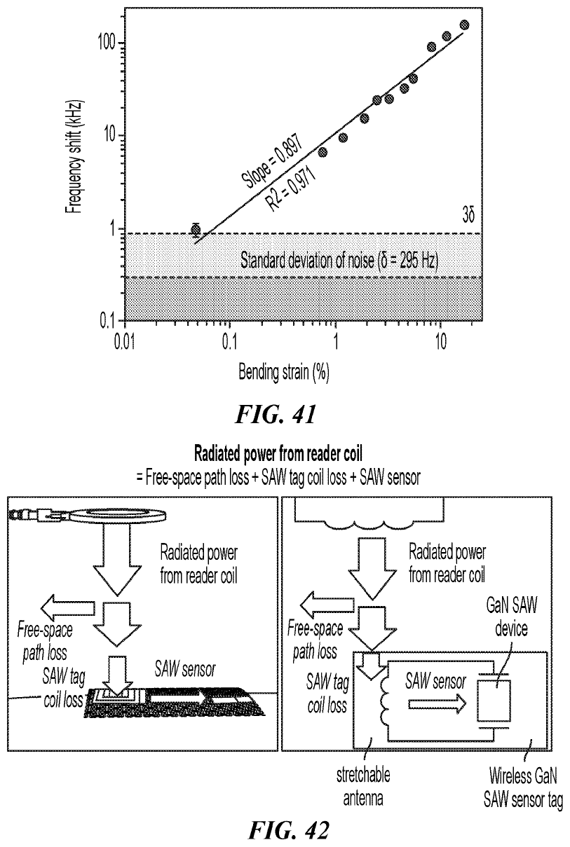

The wireless strain-sensing capability of the e-skin device was demonstrated by first calibrating the resonant peak shifts in the SAW devices in response to strain induced by bending the patch (FIGS. 19, 38A-38B, and 39). Compared with other battery-less wireless e-skin systems, the SAW-based single-crystalline e-skin device exhibits the highest strain sensitivity and the smallest minimum detectable strain of 0.048%, while consuming low power owing to its chip-less operation (FIGS. 20, 21, 40A-40B, and 41). As shown in the benchmark plot in FIG. 21, LC resonator-based e-skin systems can also achieve low-power sensing via chip-less wireless communication. However, they suffer from low sensitivity and limited sensing modality outside that of mechanical stimuli. The low sensitivity necessitates the use of highly sophisticated and costly vector network analyzers (VNAs) with low trace noise for wireless measurement. In contrast, the high sensitivity of SAW strain sensors allows wireless detection using cheap and affordable VNAs, potentially widening access to the chip-less wireless e-skin technology.

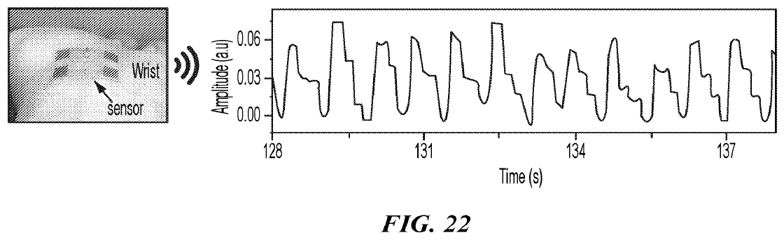

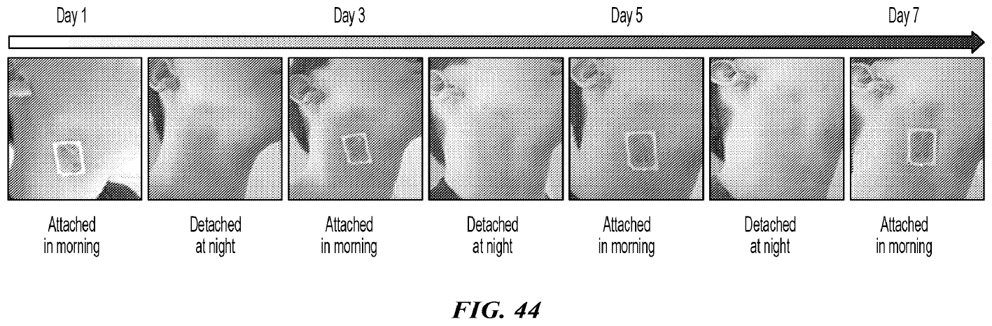

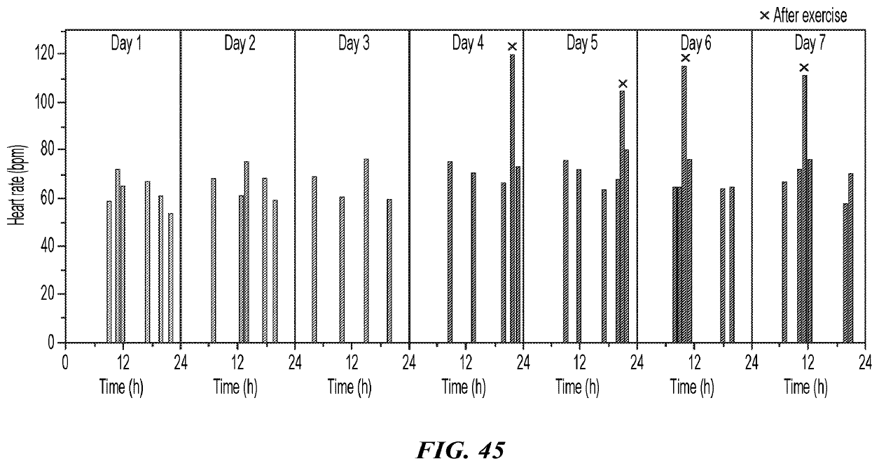

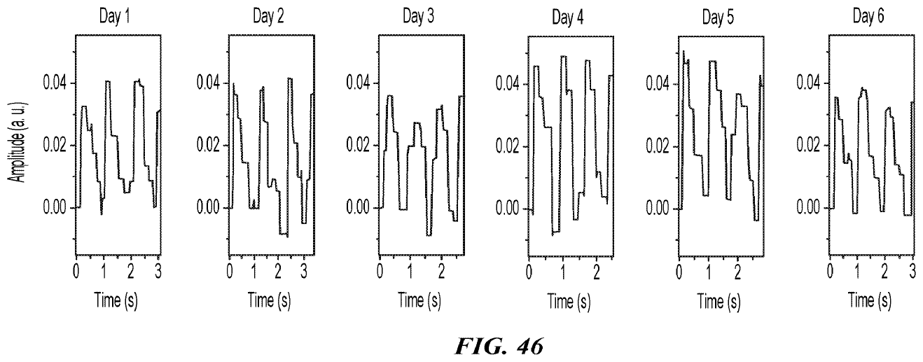

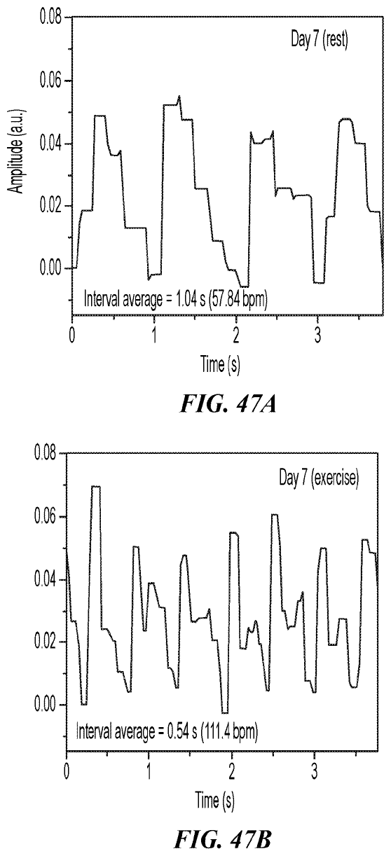

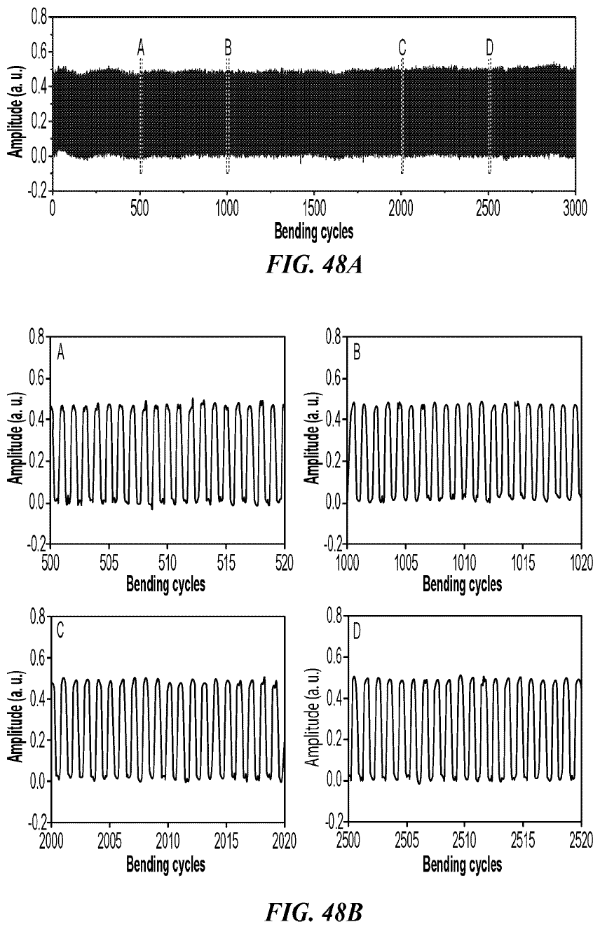

Owing to the high strain sensitivity of the SAW e-skin device, continuous chip-less wireless measurement of arterial pulse waves on the wrist was demonstrated. As shown in FIG. 22, the e-skin device continuously monitors pulse signals wirelessly without chips or batteries. The daily monitoring of heart rate and pulse waveforms was successfully conducted over a 7-day period, during which the same e-skin device was peeled off at night before sleep and re-attached in the morning (worn ˜17 hours per day; FIGS. 44, 45, 46, and 47A-47B). The wearer also carried out exercises on days 4-7 to observe changes in heart rate before and after. Continuous wireless recording of strain was also obtained using the e-skin device through 3000 bending cycles (FIGS. 48A-48B). While GaN itself is fragile, the use of thin, deformable metal interconnects with low effective modulus to electrically connect with the GaN SAW device allows the e-skin device to undergo reversible stretching or bending without fractures. All of these results strongly suggest the consistency, reusability, and long-term wearability of the GaN SAW-based e-skin device.

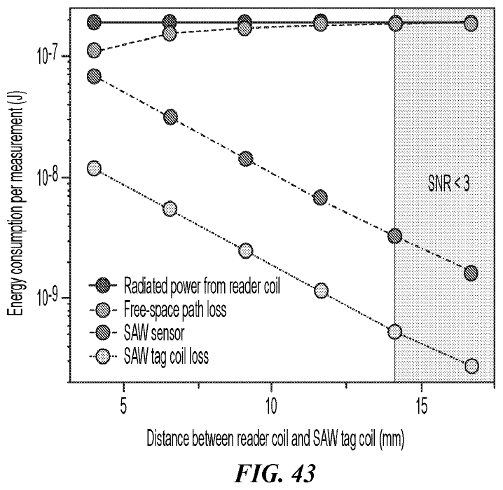

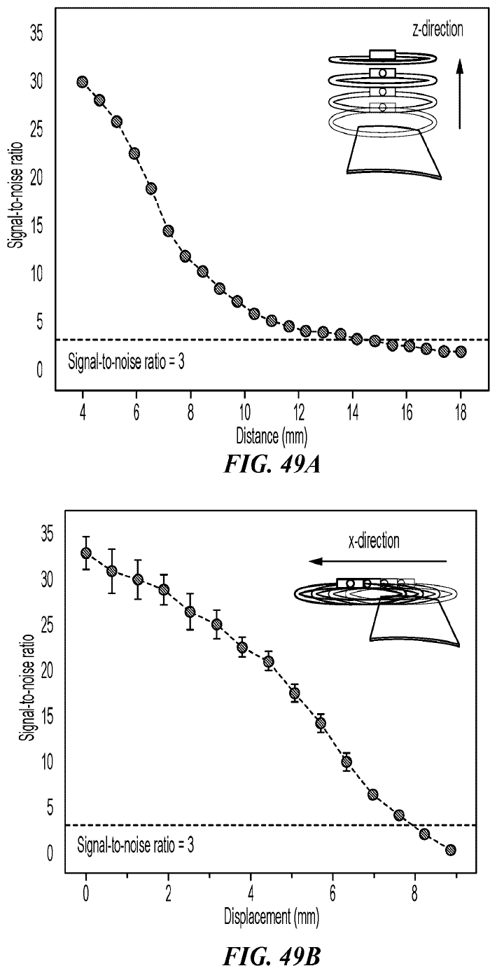

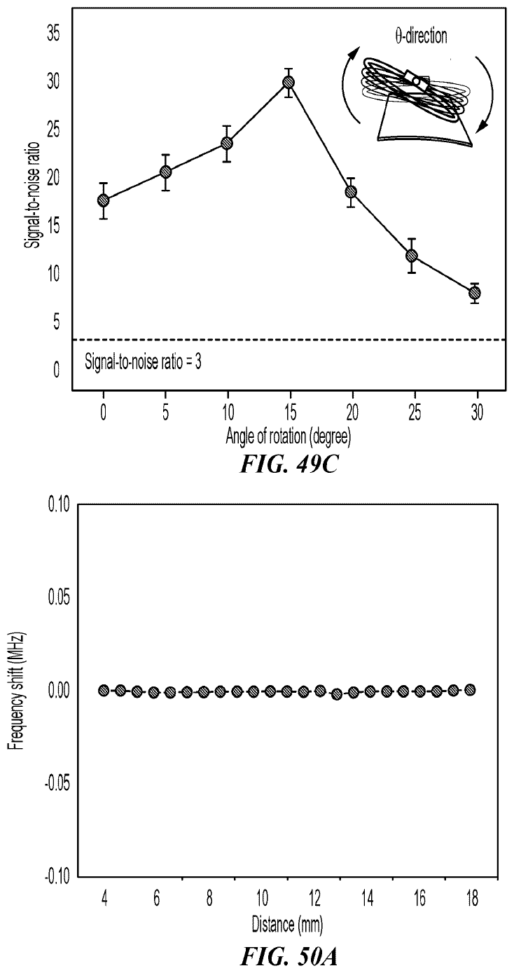

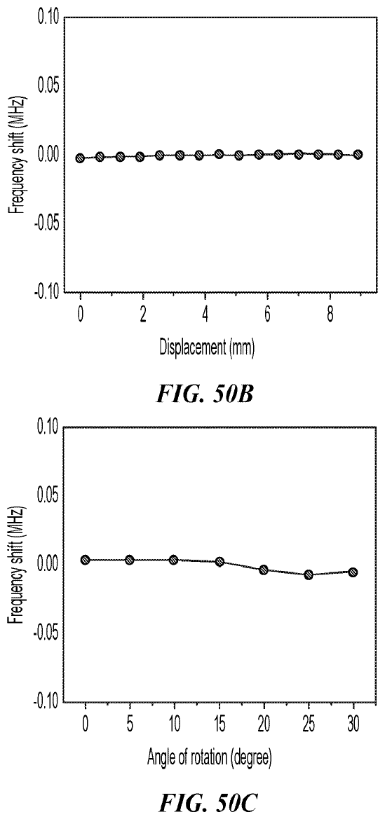

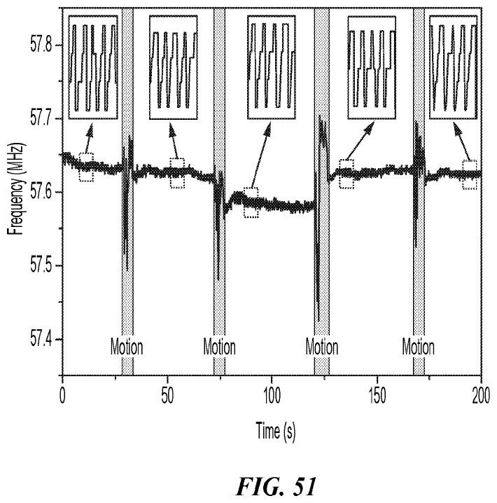

The SAW sensor's communication range, in the produced prototype, was limited to ˜14 mm. Reliable bending response was obtained upon displacement of antenna to ˜14 mm in z-direction, ˜7.5 mm in x-direction, and ˜30 degrees in θ-direction (FIGS. 49A-49C and 50A-50C). The relatively short communication range resulted in the fluctuation of antenna alignment during body movement and simultaneous measurement of body movement and heart rate could not be achieved (FIG. 51). For higher wireless ranges, the near-field electrically-small antenna of the SAW sensor tag was replaced with a far-field loop antenna. Combined with the far-field loop antenna, very low power consumption of the SAW sensor (FIG. 21) leads to long wireless communication distance (FIGS. 42-43).

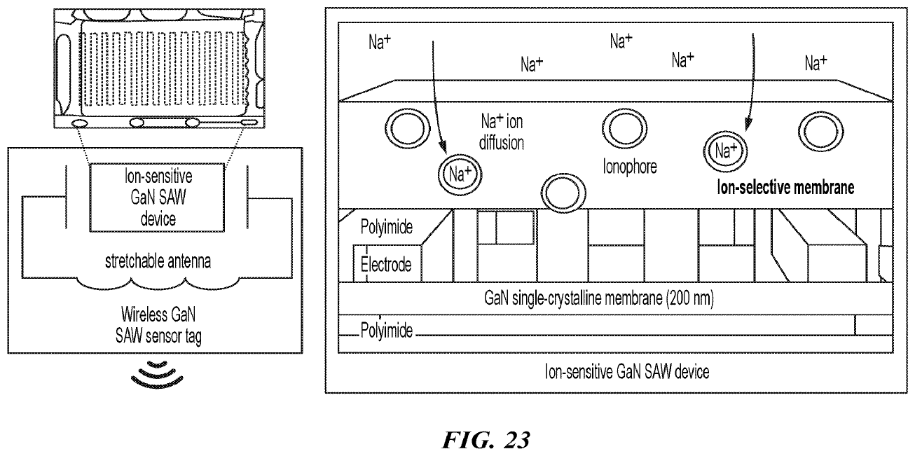

The biomedical sensing capability of the SAW-based e-skin device was expanded to wirelessly monitor ion concentrations in sweat, which can serve as indicators for conditions such as hyponatremia, kidney failure, and hypertension. The extremely small dissolution rate of GaN in most solutions makes it perform stably as a sweat sensor. The surface of the GaN SAW device was coated with ion-selective membranes (ISMs), which can trap ions inside and undergo changes in viscosity and mass. The resonant peak shifts in ISM-coated SAW device can therefore be used to wirelessly detect variation in ionic concentrations in surrounding fluids (see FIGS. 23, 52, and 61A-61B). The careful selection of ISM composition allowed successful modulation of the acoustic wave patterns in the GaN SAW device in response to variation in ion concentrations.

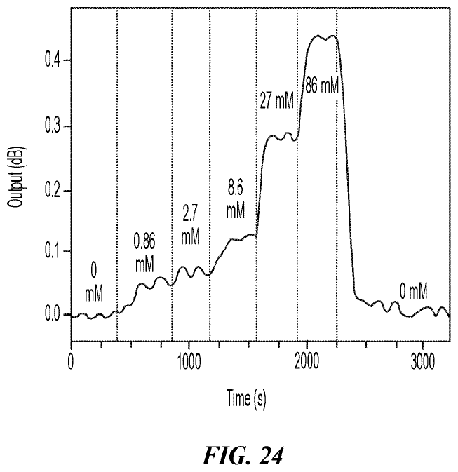

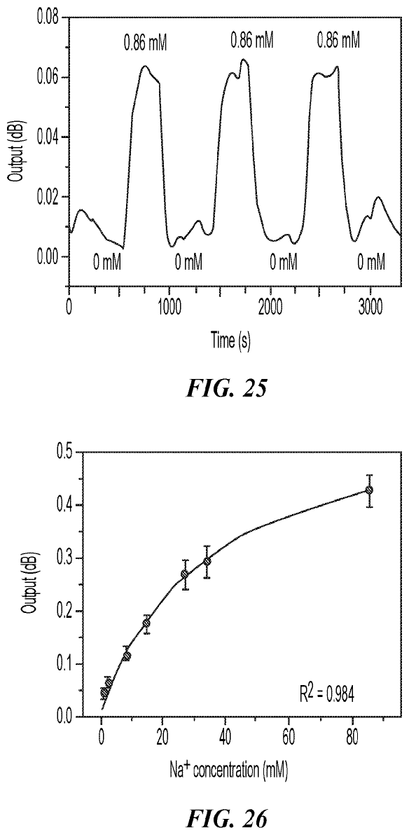

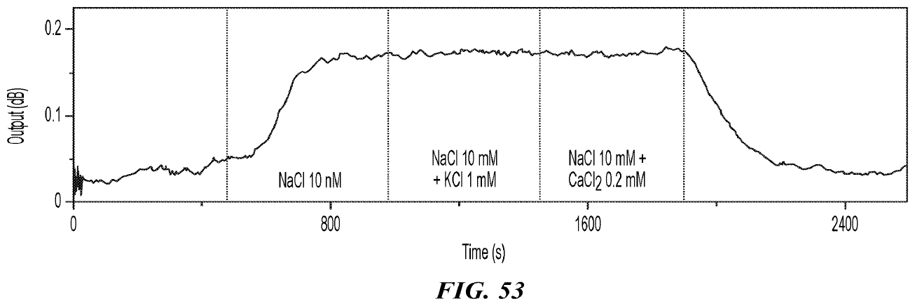

FIGS. 24, 25, and 26 illustrate the results of in vitro wireless detection of Na⁺ ion concentration using a Na⁺ ISM-coated GaN SAW e-skin device. The continuous recordings in FIGS. 24 and 25 indicate a clear and consistent responsivity and recovery of wirelessly obtained data, collected by exposing the e-skin device to aqueous NaCl solutions containing varying concentrations of sodium ions. The calibration data in FIG. 26, which are time-averaged responses of the SAW sensor during 5-minute measurements, also indicate consistent sensor behavior. For reference, 0.86 mM represents a small value compared to the biologically relevant range of Na⁺ ion concentrations in sweat, which is normally greater than 10 mM, indicating the high sensitivity of the GaN SAW ion sensor. The selective detection of Na⁺ ions was confirmed under the sequential flow of ionic solutions with different ionic compositions that resemble the composition of sweat as shown in FIG. 53.

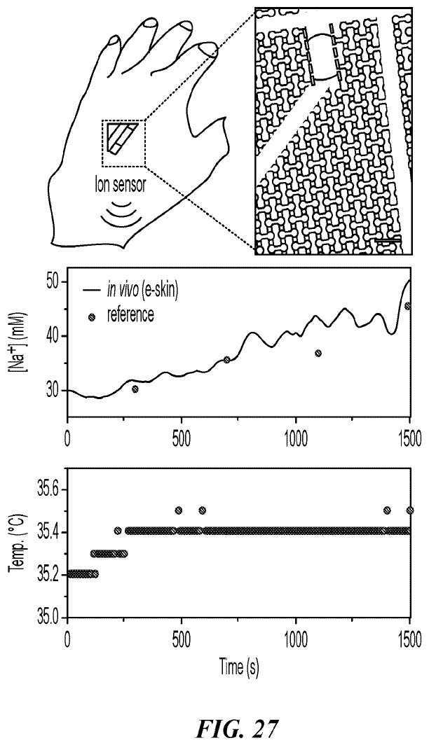

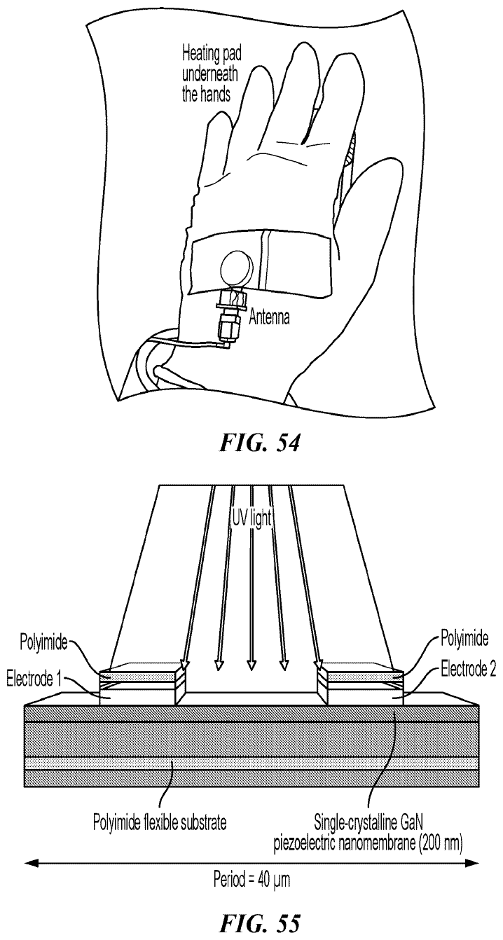

FIG. 27 shows a photograph of the GaN SAW-based e-skin device attached on the back of a hand for in vivo sweat analysis (FIG. 54). Continuous wireless recordings of the Na⁺ ion concentration in sweat was obtained using the SAW sensor and a reference conductometer, while the skin temperature was recorded simultaneously by a commercial thermometer. As the skin temperature gradually increased due to placement of a heating pad underneath the hand, the concentration of Na⁺ ions in sweat also increased over time, as confirmed by both SAW sensor and conductometer. Integrating different types of ISMs with the SAW device offers the potential to yield chip-less wireless e-skins capable of monitoring more diverse types of ions in sweat.

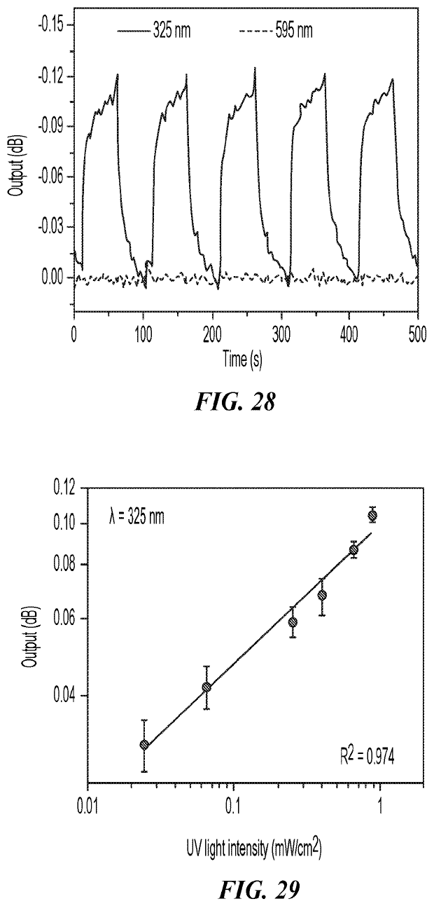

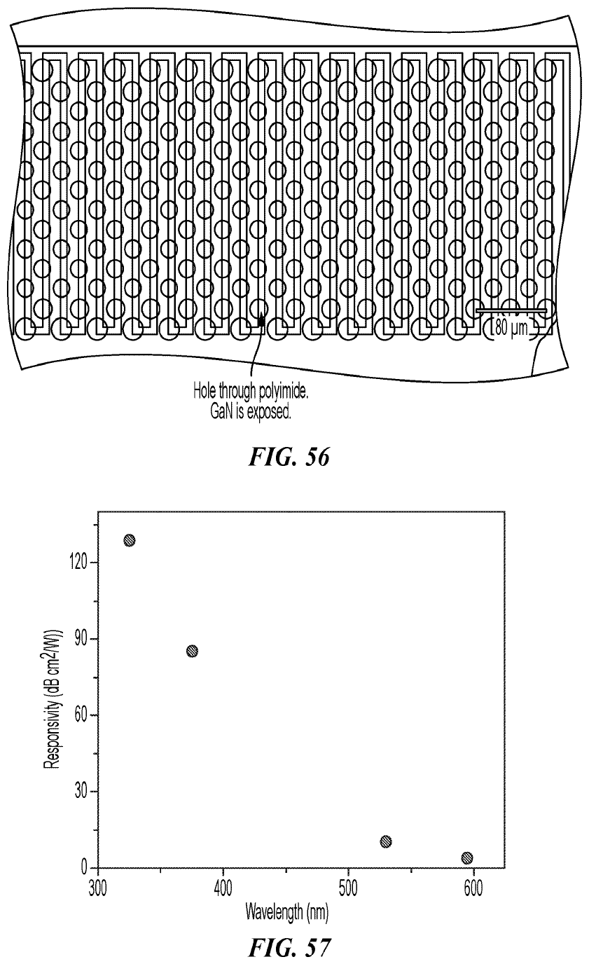

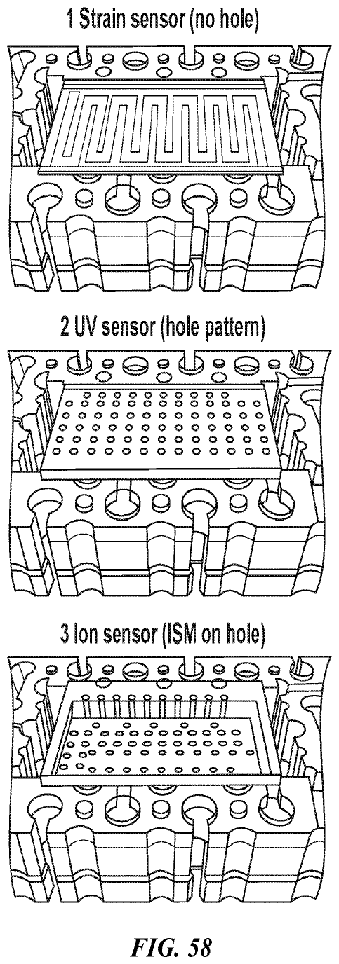

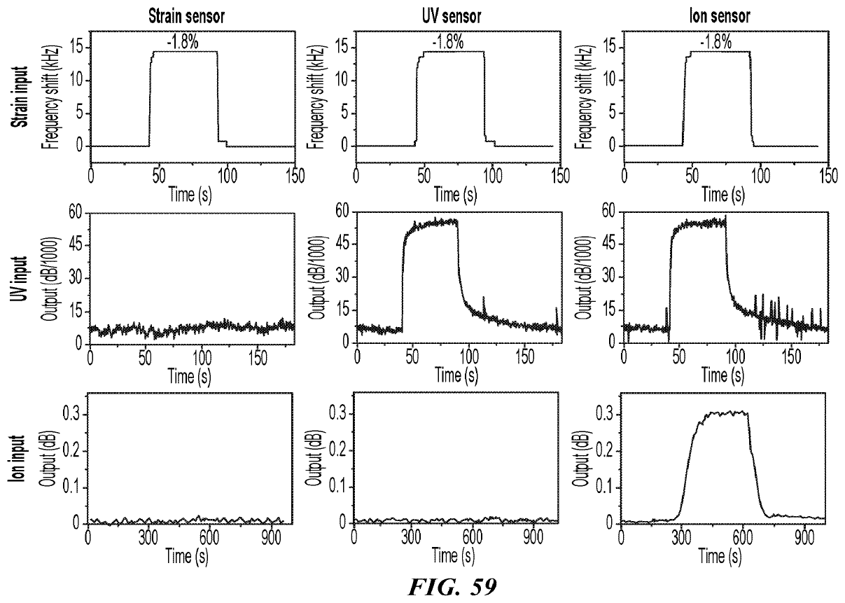

Excellent optoelectronic characteristics and piezoelectricity of GaN also allow wireless detection of UV light using the e-skin device. Light absorption by the GaN SAW device leads to variation in its electrical conductivity, which in turn alters the patterns of acoustic wave generation. The SAW sensor was first exposed to UV light by forming holes through the polyimide protection layer coating the device (FIGS. 55 and 56). FIG. 28 shows continuous wireless recordings collected using the SAW UV sensor in response to exposures to UV light (wavelength ˜325 nm) and white light (˜595 nm), indicating the strong selectivity of the device to UV light due to the matching band gap of GaN (FIG. 57). Calibration data in FIG. 29 shows the clear responsivity of the sensor to varying UV intensities. Compared to conventional photodetectors, the SAW-based UV sensor has a simpler design due to the omission of an optical filter layer. The ion and UV sensing capabilities of the GaN SAW-based e-skin device illustrate the diverse sensing options that can be achieved using the chip-less wireless platform. The cross-selectivity of the three different types of sensors (strain, UV, and ion) under three different input stimulus (strain, UV, and NaCl solution) was also confirmed as shown in FIGS. 58 and 59. By fully utilizing the electronic/optoelectronic/piezoelectric characteristics of GaN freestanding membranes, highly sensitive chip-less wireless monitoring of physiological data was achieved.

In summary, chip-free e-skin platforms utilizing GaN SAW devices for sensing and wireless communications were fabricated. The GaN SAW devices were built using single-crystalline, ultrathin, freestanding, and piezoelectric GaN films prepared by remote epitaxy. Remote homoepitaxy of GaN allowed buffer layer-free growth of ultrathin GaN epitaxial layers, which were readily released from substrates. The freestanding and highly crystalline nature of the films enable the SAW devices with a very high electromechanical coupling coefficient (k²). The GaN SAW devices enable wireless e-skin systems with high sensitivity and low power consumption, without the use of bulky wireless integrated circuit chips. The e-skin device can be used for wireless monitoring of strain, UV light, and ions for biosensing applications via combination with a wide variety of biomolecular binder types, therefore opening new directions for implementing highly sensitive and power-saving versatile wireless e-skin devices.

The following describes the materials and methods used to fabricate and characterize the chip-less wireless e-skin-based health monitoring sensor device based on a SAW resonator, described above.

Production of GaN nanomembranes via remote homoepitaxy: A Veeco Gen200 plasma-assisted molecular beam epitaxy system was used to grow GaN thin films on 2D materials coated GaN substrates. The GaN substrates were commercial 5 μm GaN grown on sapphire. Prior to growth, the GaN substrate were cleaned by acetone, IPA and HCl before loading into the reaction chamber. 1-3 layers of 2D materials were deposited on GaN substrates after being outgassed at 700° C. for 15 minutes. Then, 200 nm to 1.8 μm GaN epilayers were grown at substrate temperature from 680° C. to 730° C. Gallium rich conditions were used to ensure enhanced surface diffusion. Gallium residues were etched by FeCl₃ after growth. To exfoliate the GaN epilayer, a Ni stressor (2.5 μm) with Cr adhesion layer (30 nm) was deposited to the GaN surface which induces a mechanical strain at the GaN/2D material interface. Thermal release tape (TRT) was applied to the metal stressor/GaN multilayers, followed by lifting of the TRT from the substrate edge, resulting in mechanical exfoliation of the GaN nanomembranes with the metal stressors. The whole process is illustrated in FIG. 30.

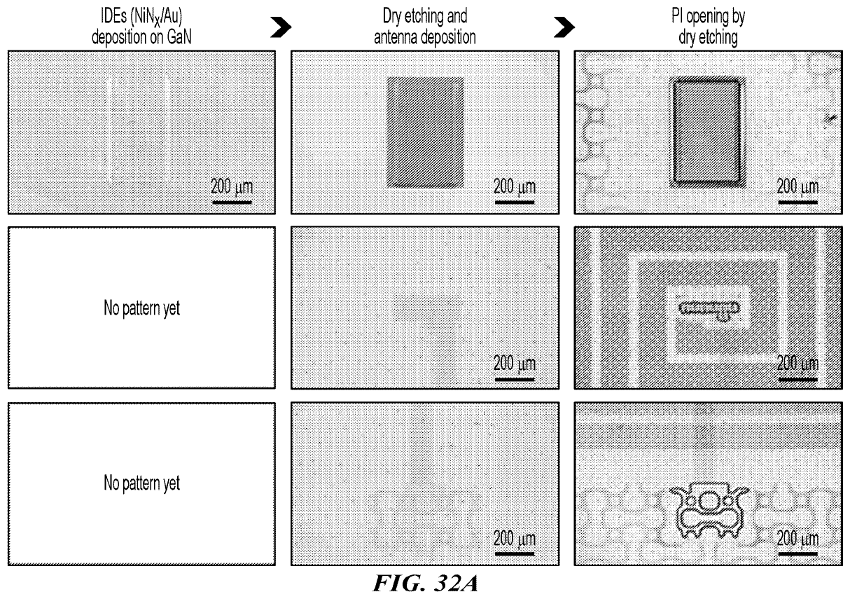

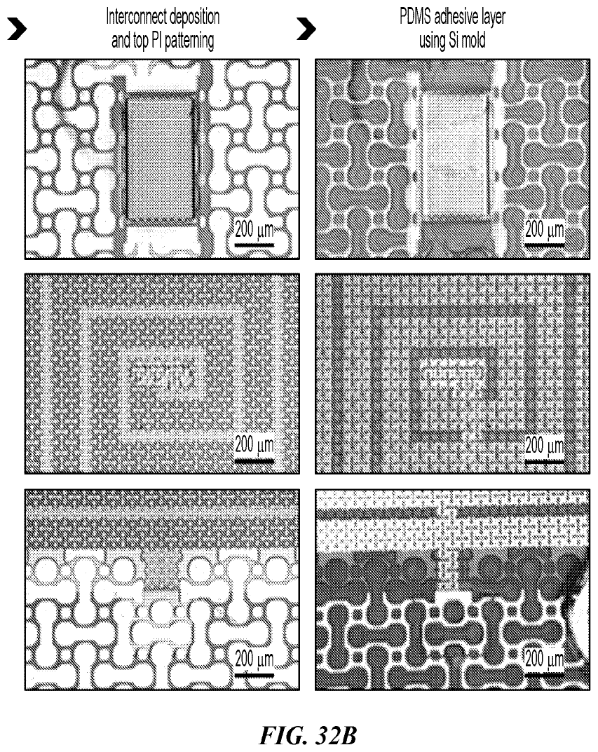

Fabrication of electronic modules in perforated e-skin devices: Singe-crystalline GaN nanomembranes (200 nm) were fabricated by remote homoepitaxy processes as piezoelectric, wide bandgap semiconductor layers of strain sensors and UV sensors. For fabrication of single-crystalline GaN e-skin devices, a polyimide precursor, poly(pyromellitic dianhydride-co-4,4′-oxydianiline) in n-methyl-2-pyrrolidone (purchased from Sigma Aldrich), was spin coated and cured on Al/Ti (500 nm/20 nm)-coated, heavily-doped Si substrate (<0.01 Ωcm) at 300° C. for 1 hour. An epoxy resin (FIG. 35) with a glass transition temperature (T_{g}) higher than those of commonly used adhesives, such as PDMS and SU-8, was used for bonding to avoid viscous behavior of adhesives at the curing temperature (>250° C.) of the polyimide. Both sides of the substrate and the GaN nanomembranes were treated with (3-aminopropyl)triethoxysilane (APTES) solution in water (10 μL/20 mL) before bonding using a toluene solution of epoxy precursors made of 4,4′-methylenebis (N,N-diglycidylaniline) and 4,4′-diaminodiphenylmethane (both purchased from Sigma-Aldrich). After spin coating of the epoxy resin (1 μm) on the substrate, exfoliated GaN nanomembranes/Cr/Ni stressor multilayers on a handling elastomer consisting of styrene-ethylene/butylene-styrene, SEBS (Tuftec H1221 from AsahiKasei), and PDMS (Sylgard 184 from Dow Corning, base 10: crosslinker 1) were placed on the uncured, sticky resin, and spatially uniform pressure was applied using a vise during curing of the epoxy resin at 150° C. for 1 hour to create a flat surface on the bonded region. The cured epoxy resin did not melt in the high temperature curing of polyimide. After bonding, the elastomer holding the multilayers was detached in toluene and the Ni/Cr layers were removed by FeCl₃ solution and ammonium cerium (IV) nitrate (40 mg/mL, Sigma-Aldrich). The photoresist (AZnLOF2035, MicroChem) was patterned on the bonded GaN surface and NiN (20 nm) was deposited by reactive-sputtering under flow of N₂ to form a Schottky contact on the exposed GaN surface for piezotronic strain sensors and UV sensors. The exposed GaN surface was cleaned using HCl solution before the NiN electrode formation to form a good Schottky barrier. The subsequent Au (20 nm) deposition by e-beam evaporator and lift-off process resulted in interdigitated electrodes (IDEs) with 10 μm inter-spacing. On the IDEs-deposited GaN, a thick photoresist (AZ10xt, MicroChem) was patterned as a mask to passivate GaN active regions during dry etching (inductively coupled plasma, 5 mtorr, Cl₂ 25 sccm, Ar 25 sccm, bias 70 W, plasma 500 W). APTES was treated again, and planarizing polyimide was spin coated and cured at 300° C. for 1 hour. The photoresist (AZnLOF2035, MicroChem) was once again patterned to deposit bottom antenna electrodes followed by e-beam evaporation of Ti (2 nm) and Au (100 nm) with subsequent lift-off process. APTES was treated once more, and another layer of planarizing polyimide was spin coated and cured at 300° C. for 1 hour. The photoresist (AZ10xt, MicroChem) was patterned for a mask to etch away the polyimide layer (inductively coupled O₂ plasma, O₂ 45 sccm, plasma 500 W) for electrical connection of IDEs on the GaN active region and bottom antenna electrodes to metal interconnects which are to be deposited on top of the polyimide layer. After photoresist (AZnLOF2035, MicroChem) patterning, e-beam evaporation of Ti (2 nm), Au (100 nm), and Ti (5 nm) was conducted to form metal interconnects with auxetic dumbbell-hole patterns. The top PI layer (2 μm) was formed on the entire sample surface to locate electronic circuits near neutral mechanical plane, thereby improving mechanical robustness. Some interfaces among layers were treated with APTES 1% v/v in deionized water to improve interface strength. Finally, after the PI layers were patterned by photoresist (AZ10xt, MicroChem) and etched away (inductively coupled O₂ plasma, O₂ 45 sccm, plasma 500 W), the fabrication of the auxetic dumbbell hole patterned electronic modules was completed. Whole processes are illustrated in FIGS. 31A-31D with corresponding optical microscopy images in FIGS. 32A-32B.

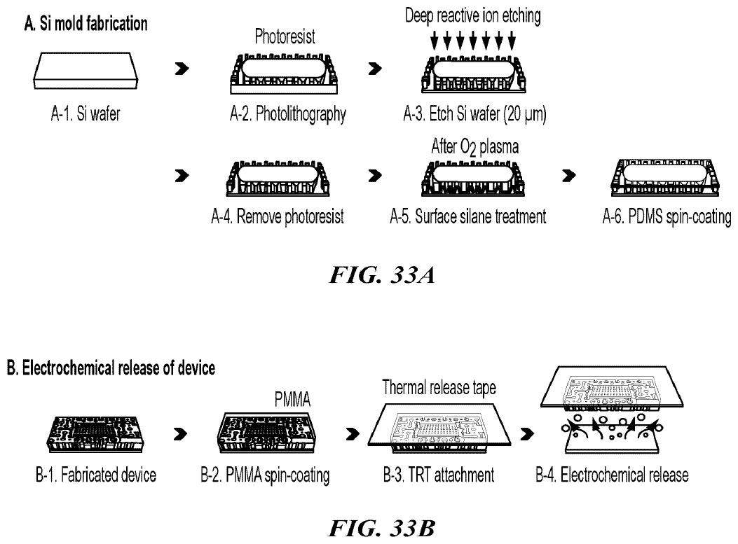

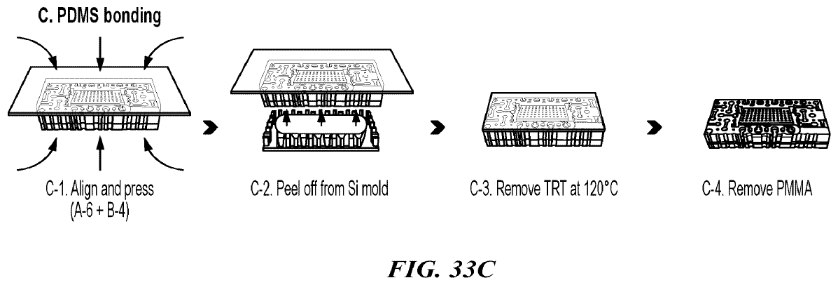

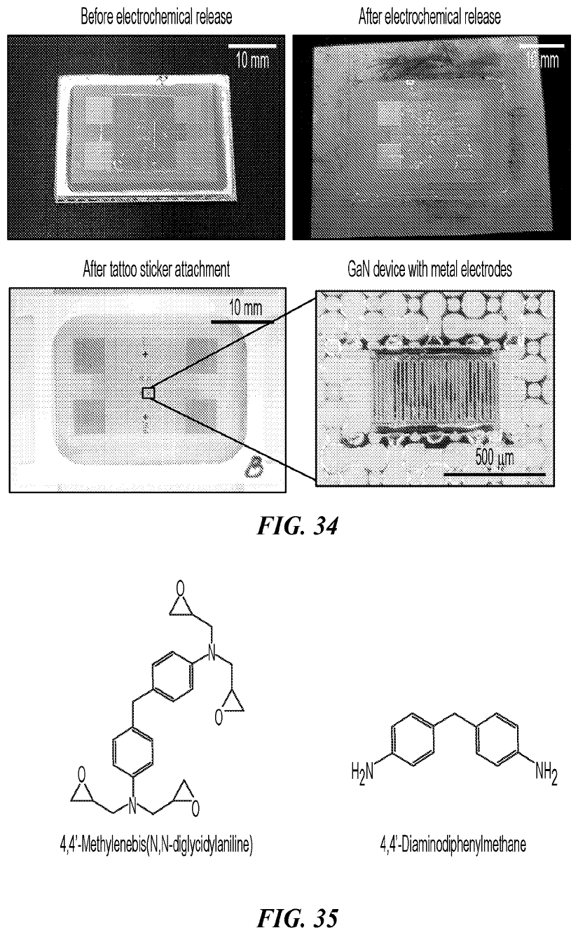

Perforated e-skin fabrication: For integration of the electronic modules to the auxetic dumbbell hole patterned polydimethylsiloxane (PDMS) adhesives (SYLGARD 184, Dow Corning), detachment of the electronic modules from the Al/Ti/Si wafer by electrochemical lift-off process (dissolution of Al layer) was the first step. Before the lift-off process, the electronic modules were attached to TRT. Between modules and TRT, a 2-μm-thick poly(methyl methacrylate) (PMMA) layer was inserted. After electrical wiring at the backside of the Si substrate, the samples were dipped into sodium chloride solution (0.9% NaCl) together with Pt wire as a counter electrode. As 1.8 V was applied to the Si wafer, the Al was dissolved in NaCl solution and electronic modules were transferred to the TRT accordingly. To form auxetic dumbbell hole patterns on the electronic modules and the PDMS adhesives, Si mold-based soft lithography processes were utilized (FIGS. 33A-33B). First, a dumbbell-shaped Si mold (˜20 μm depth) was prepared by deep reactive-ion etching (DRIE). After spin coating of off-stoichiometric PDMS gels (40:1 weight ratio of PDMS pre-polymer:curing agent) on the Si mold, the electronic modules with TRT were placed on the uncured PDMS. Semi-transparency of the TRT allowed the auxetic dumbbell mesh of the electronic circuits to be aligned with the Si mold. After the alignment, the PDMS layer was cured at 80° C. with a constant pressure (1.29 kPa) to maximize the yield of the through-hole formation in the e-skin device. After PDMS curing, the Si mold was separated from the samples. The Si mold was treated with trichloro(1H, 1H, 2H, 2H-perfluorooctyl)silane to reduce the Si surface energy, while APTES treatment was conducted on the surface of the electronic modules right before placing onto the uncured PDMS adhesives. Thus, the interface strength between the electronic modules and PDMS adhesive was much stronger than Si mold/PDMS interface strength, and such interface engineering processes facilitated the transfer of PDMS adhesives to the electronic modules without notable damages. After aligned bonding with the perforated electronic modules and the perforated PDMS adhesives, the TRT was detached by heating at 150° C. and the samples were dipped into acetone to remove PMMA. As the PMMA layer was dissolved, the perforated e-skin device was produced. The perforated e-skin was scooped from acetone using cellulose wipers (TX2009, Texwipe) and cleaned by isopropanol. After drying of the perforated e-skin device on the wipers, the edge of the perforated e-skin was attached to a temporary tattoo paper (Silhouette) which acts as a temporary handling layer (FIG. 34).

Preparation of skin replica: Dragon Skin silicone (1:1 ratio of part A to part B by weight; Dragon Skin 30; Smooth-On, Inc.) was poured on the forearm, allowed to cure for ˜1 hour at room temperature, removed from skin, and placed in a Petri dish with the skin-textured side facing upward. Pouring Ecoflex (1:1 ratio of part A to part B by weight; Ecoflex 30; Smooth-On, Inc.) into the Petri dish, letting it cure at room temperature for ˜12 hours, and peeling it away yielded the skin replica samples made of Ecoflex.

GaN film characterization: The structural properties of GaN thin films were characterized by using a Bruker D8 high-resolution X-ray diffraction. Surface morphologies of GaN thin films were measured by using a Zeiss Merlin scanning electron microscope and by using a Park NX10 atomic force microscope (AFM). For dislocation density determination, GaN thin films were etched in phosphoric acid at 160° C. for 0.5 hours. For TEM, the cross-sectional specimens were extracted from the GaN thin film by a lift-out technique in a dual-beam FIB/SEM (Helios G4, Thermo Fisher Scientific, U.S.). Prior to the ion-milling in a FIB/SEM, layers of carbon were deposited on the sample surface to protect the sample. The inner structures of single-crystalline GaN were observed using an aberration-corrected TEM (ARM-200F, JEOL, Japan) on the cross-sectional specimens at an acceleration voltage of 200 kV. The microscope was equipped with an aberration corrector in the objective lens (image corrector) and a Gatan OneView camera.

Evaluation of UV sensing performance: UV conformal photocurrent microscopy (UVCPM) system was established to assess UV sensing performance of single-crystalline GaN and polycrystalline GaN. The output currents from sensors were recorded with varying biases and illumination intensity by an Agilent B1500A semiconductor device parameter analyzer.

Measurement of SAW e-skin device: A handheld low-cost open hardware vector network analyzer (VNA), NanoVNA H4, or a tabletop laboratory VNA, Agilent N5230A VNA (as a comparison to NanoVNA), were used for measurements of SAW devices (FIG. 36). A magnet wire made of a metal wire covered with very thin insulation was used to build a reader antenna. The reader antenna was connected to the VNA. Dumbbell-shaped Ti/Au/Ti (2 nm/100 nm/5 nm) electrodes were used to build a stretchable antenna and a stretchable interconnect between the stretchable antenna and a GaN SAW device. The reader antenna was wirelessly coupled with the stretchable antenna on the GaN SAW e-skin sensor tag. The data rate achieved by the measurement system was approximately 31.39 Hz.

Evaluation of wireless UV sensor performance: The GaN SAW e-skin device had hole patterns etched through the top polyimide layer to expose the GaN surface to UV light. The UCVPM system was used, and the output signals upon irradiation of UV light with varying intensities (24.65 μW/cm², 65.64 μW/cm², 256.2 μW/cm², 403.4 μW/cm², 671.0 μW/cm², and 898.5 μW/cm²) were recorded by VNA.

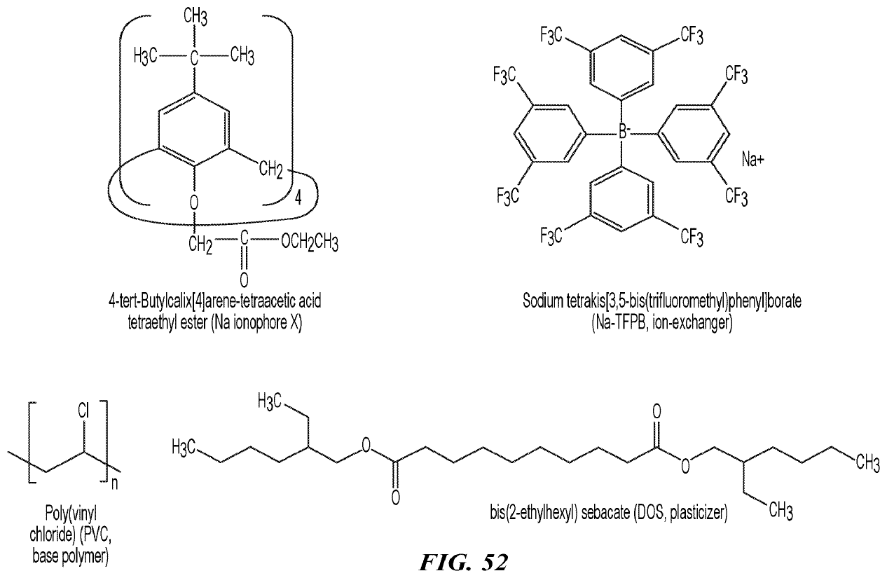

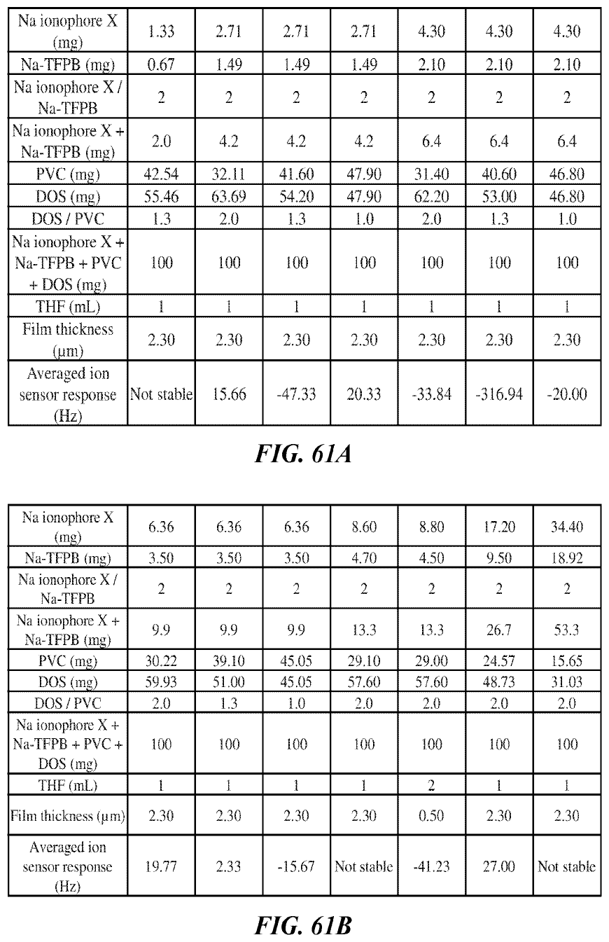

Fabrication and evaluation of ion sensing performance: The GaN SAW e-skin device had hole patterns etched through the top polyimide layer. On top of either the GaN SAW e-skin device or quartz crystal microbalance (QCM), ion-selective membrane solutions in tetrahydrofuran (FIGS. 52 and 61A-61B) were spin coated at 3000 rpm. The ion-selective membrane was dried at 80° C. for 5 minutes. The resulting GaN SAW e-skin ion sensors and QCM ion sensors were tested using an Agilent N5230A vector network analyzer and a Biolin Scientific Q-Sense E4 system, respectively. NaCl solutions containing different Na⁺ ion concentrations were pumped over the e-skin device using peristaltic pumps at a flow rate of 0.184 mL/min. Alternating injections of 0.86 mM NaCl solution and distilled water over the device yielded the wireless recordings in FIG. 25. To obtain the calibration curve in FIG. 26, output signals were collected by the SAW e-skin sensor exposed to varying concentrations of Na⁺ ions (0.86 mM, 2.71 mM, 8.56 mM, 14.92 mM, 27.05 mM, 34.22 mM, and 85.56 mM) for 5 minutes each. The collected data were time-averaged and plotted as a function of the Na⁺ ion concentration.

COMSOL Multiphysics simulation: Finite element analysis of the GaN SAW e-skin device was evaluated using COMSOL Multiphysics software. The geometry of the device, drawn two-dimensionally, is shown in FIG. 15. The interdigital transducer (IDT) electrodes were periodic with a length of 10 μm, a spacing of 10 μm, and a period of 40 μm. The thickness of IDT electrodes was 40 nm, and the width of IDT electrodes in the direction orthogonal to the 2 drawing plane was 268 μm. GaN thickness was varied. The thickness of the top polyimide was 760 nm, and the thickness of bottom polyimide was 1.72 μm. The bottom sapphire was set to be 120 μm, which is 3 times the period of SAW. The elasticity matrix and coupling matrix values of GaN were obtained from literature. Solid Mechanics and Electrostatics physics interfaces were used. The upper boundary of the top polyimide and the lower boundary of the bottom polyimide were set to be free boundaries. The lower boundary of the bottom sapphire was fixed. The periodic conditions were applied to the left and right boundaries of the drawn 1 period of geometry. All the geometry was under mechanical damping, and the piezoelectric domain had additional conduction loss. The two electrodes functioned as ground and terminal. Frequency domain analysis was used to calculate the conductance, G=Re(Y), and the susceptance, B=Im(Y), between the two electrodes. The electromechanical coupling coefficient (k²) was calculated using the equation,

$${k}^{2} = \frac{π}{4 N} {( \frac{G}{B} )}_{f = {f}_{r}} ,$$

where N and fᵣ are the number of IDT finger pairs and resonant frequency, respectively.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A surface acoustic wave resonator, comprising:
a substrate; and
a single-crystalline piezoelectric material positioned at least partially over the substrate;
wherein:
the single-crystalline piezoelectric material has a thickness of less than or equal to 300 nm and/or the resonator has a minimum detectable strain less than or equal to 0.1% at an energy consumption less than or equal to 8×10⁻⁸ Joules per measurement; and
the resonator is configured such that the single-crystalline piezoelectric material resonates to generate a mechanical wave during operation of the resonator.

2. The surface acoustic wave resonator of claim 1, wherein the resonator has a minimum detectable strain less than or equal to 0.1% at an energy consumption less than or equal to 8×10⁻⁸ Joules per measurement.

3. (canceled)

4. The surface acoustic wave resonator of claim 1, wherein the resonator has a minimum detectable strain less than or equal to 0.05% at an energy consumption less than or equal to 8×10⁻⁸ Joules per measurement.

5. The surface acoustic wave resonator of claim 1, wherein the single-crystalline piezoelectric material comprises a semiconductor material.

6. The surface acoustic wave resonator of claim 1, wherein the substrate comprises a cavity.

7. The surface acoustic wave resonator of claim 6, wherein the single-crystalline piezoelectric material is positioned at least partially over the cavity of the substrate.

8. The surface acoustic wave resonator of claim 1, wherein the single-crystalline piezoelectric material is or is part of a freestanding layer.

9. The surface acoustic wave resonator of claim 8, wherein the freestanding layer has a thickness of at least 10 nm.

10. The surface acoustic wave resonator of claim 8, wherein the freestanding layer has a thickness of less than or equal to 100 mm.

11. A device, comprising:
a substrate comprising a cavity; and
a single-crystalline material positioned at least partially over the cavity of the substrate, wherein:
the single-crystalline material is or is part of a freestanding layer; and
the single-crystalline material has a thickness of less than or equal to 300 nm.

12. The device of claim 11, wherein the single-crystalline material comprises a single-crystalline piezoelectric material.

13. The device of claim 12, wherein the single-crystalline piezoelectric material comprises a semiconductor material.

14. The surface acoustic wave resonator of claim 1, further comprising a plurality of interdigitated electrodes.

15. The surface acoustic wave resonator of claim 14, wherein the plurality of interdigitated electrodes is in electrical communication with the single-crystalline piezoelectric material.

16. (canceled)

17. The surface acoustic wave resonator of claim 14, wherein the plurality of interdigitated electrodes are patterned.

18. The surface acoustic wave resonator of claim 14, further comprising an antenna.

19-26. (canceled)

27. A method of forming a device, comprising:
transferring a single-crystalline material from a growth substrate to a receiving substrate such that at least a portion of the single-crystalline material is positioned over a cavity of the receiving substrate,
wherein, after the transferring, the single-crystalline material is or is part of a freestanding layer, and the single-crystalline material has a thickness of less than or equal to 300 nm.

28-29. (canceled)

30. A method of operating the surface acoustic wave resonator of claim 1, comprising:
applying an electrical potential to the surface acoustic wave resonator such that the single-crystalline piezoelectric material resonates to generate a mechanical wave; and
determining a change in a resonant frequency of the single-crystalline piezoelectric material in response to an environmental change.

31-33. (canceled)

34. The surface acoustic wave resonator of claim 1, wherein the single-crystalline piezoelectric material has a thickness of less than or equal to 300 nm.
